(19) United States
(12) Patent Application Publication
(10) Pub. No.: US 2024/0337689 A1
(43) Pub. Date: Oct. 10, 2024

(54) RADIATION EVALUATION FOR SEMICONDUCTOR DEVICE

(71) Applicant: QRT Co., Ltd., Icheon-si (KR)

(72) Inventors: Young Boo KIM, Yongin-si (KR); Sung Soo CHUNG, Ansan-si (KR); Joong Sik KIH, Seoul (KR); Ki Seog KIM, Yongin-si (KR); Hyeok Jae LEE, Yongin-si (KR); Nam Ho KIM, Icheon-si (KR); Muhammad Saqib KHAN, Suwon-si (KR); Jie Seok KIM, Suwon-si (KR); Seung Han SHIN, Yongin-si (KR)

(73) Assignee: QRT Co., Ltd., Icheon-si (KR)

(21) Appl. No.: 18/748,924

(22) Filed: Jun. 20, 2024

Related U.S. Application Data
(63) Continuation of application No. PCT/KR2021/019967, filed on Dec. 27, 2021.
(63) Continuation of application No. PCT/KR2021/019968, filed on Dec. 27, 2021.

(30) Foreign Application Priority Data
Dec. 22, 2021 (KR) 10-2021-0185196
Dec. 22, 2021 (KR) 10-2021-0185197

(51) Int. Cl. G01R 31/302

(52) U.S. Cl. CPC G01R 31/302

(57) ABSTRACT

A system is configured to evaluate a semiconductor device. The system is for irradiating a test target semiconductor device arranged on a test board with a radiation test beam to measure an error value of the test target semiconductor device, wherein the test target semiconductor device includes a reference test target semiconductor device and a general test target semiconductor device, the system for evaluating the semiconductor device derives a reference error value of the reference test target semiconductor device and a reference error value of the general test target semiconductor device, and the reference error value of the general test target semiconductor device is able to be defined as a relative ratio to the reference error value of the reference test target semiconductor device.

### CROSS-REFERENCE TO RELATED APPLICATIONS

This application is a continuation of International Application PCT/KR2021/019967 (filed 27 Dec. 2021), which claims the benefit of Republic of Korea Patent Application KR 10-2021-0185196 (filed 22 Dec. 2021). This application is a continuation of International Application PCT/KR2021/019968 (filed 27 Dec. 2021), which claims the benefit of Republic of Korea Patent Application KR 10-2021-0185197 (filed 22 Dec. 2021). Each of these priority applications is hereby incorporated by reference herein.

### TECHNICAL FIELD

The present disclosure relates to a method for evaluating a radiation of a semiconductor device and a system for evaluating a radiation of a semiconductor device, and more particularly, to a method for evaluating a semiconductor device and a system for evaluating of a semiconductor device, capable of measuring an error value caused by a radiation of a test target semiconductor device by a radiation test beam with which a test board is irradiated.

In addition, the present disclosure relates to a method for evaluating a radiation of a semiconductor device, a system for evaluating a radiation of a semiconductor device, a method for evaluating a beam characteristic, and a system for evaluating a beam characteristic, and more particularly, to a method for evaluating a semiconductor device, a system for evaluating a semiconductor device, a method for evaluating a beam characteristic, and a system for evaluating a beam characteristic, by using a reference semiconductor device.

### BACKGROUND ART

Semiconductor test equipment may be broadly classified into a main tester, a probe station, a handler, and burn-in equipment, and may be classified into: wafer test equipment configured to test whether a chip is normal in a wafer state, such as a probe station; component test equipment configured to evaluate a normal operation state of a package at a final stage after finishing pre- and post-semiconductor processes, such as a handler; and module test equipment configured to test a properly operating state in a module state where a plurality of semiconductor devices are mounted on a PCB.

As semiconductor devices are miniaturized, various semiconductor evaluation apparatuses are being developed.

For example, Korean Patent Registration Publication No. 10-1679527 has disclosed a semiconductor device test apparatus including: a light generation unit configured to generate a light with which a semiconductor device, which is a test target device, is irradiated; a test signal application unit configured to apply a test signal for driving the semiconductor device to the semiconductor device; a light detection unit configured to detect a reflection light reflected from the semiconductor device when the semiconductor device is irradiated with the light, and output a detection signal; a first spectrum analyzer configured to receive the detection signal, and measure first phase information, which is phase information of the detection signal; a reference signal generation unit configured to generate a reference signal having a predetermined frequency; a second spectrum analyzer configured to receive the reference signal, and measure second phase information, which is phase information of the reference signal; and an analysis unit configured to derive phase information of the detection signal at the predetermined frequency based on the first phase information and the second phase information, wherein the first spectrum analyzer measures the first phase information for a frequency of the reference signal that operates the first spectrum analyzer, the second spectrum analyzer measures the second phase information for a frequency of the reference signal that operates the second spectrum analyzer, and the frequency and a phase of the reference signal of the first spectrum analyzer are synchronized with the frequency and a phase of the reference signal of the second spectrum analyzer, respectively.

### Technical Problem

One technical object of the present disclosure is to provide a method for evaluating an impact of radiation particles on a semiconductor device and a system for evaluating a semiconductor device.

Another technical object of the present disclosure is to provide a method for evaluating a semiconductor device and a system for evaluating a semiconductor device, capable of measuring an error value of a test target semiconductor device by a test beam by using a radiation or radiation particles with which a test board is irradiated.

Still another technical object of the present disclosure is to provide a method for evaluating a semiconductor device and a system for evaluating a semiconductor device, capable of defining reference error values of a plurality of test target semiconductor devices.

Yet another technical object of the present disclosure is to provide a method for evaluating a semiconductor device and a system for evaluating a semiconductor device, capable of minimizing an error value between an evaluation value and a dose value of the semiconductor device according to a dose difference in consideration of the dose difference according to a region of a test beam.

Still yet another technical object of the present disclosure is to provide a method for evaluating a radiation of a semiconductor device by using a reference semiconductor device and a system for evaluating a radiation of a semiconductor device by using a reference semiconductor device.

Another technical object of the present disclosure is to provide a method for evaluating a beam characteristic by using a reference semiconductor device and a system for evaluating a beam characteristic by using a reference semiconductor device.

Still another technical object of the present disclosure is to provide a method for evaluating a semiconductor device and a system for evaluating a semiconductor device, capable of measuring an error value of a test target semiconductor device by a test beam with which a test board is irradiated.

Yet another technical object of the present disclosure is to provide a method for evaluating a semiconductor device, a system for evaluating a semiconductor device, a method for evaluating a beam characteristic, and a system for evaluating a beam characteristic, by using a reference semiconductor device in which a reference error value is defined.

Still yet another technical object of the present disclosure is to test a test target semiconductor device at specific energy provided by an energy control board by using a beam characteristic control board, so that sensitive energy and reaction characteristics according to the sensitive energy may be analyzed to determine a signature, which is a difference between test target semiconductor devices of the same level.

Technical objects of the present disclosure are not limited to the technical objects described above.

### Technical Solution

To achieve the technical objects described above, the present disclosure provides a method for evaluating a semiconductor device.

According to one embodiment, the method for evaluating the semiconductor device includes: preparing a test board; arranging a test target semiconductor device in a test region of the test board; and irradiating the test region of the test board with a test beam to measure an error value of the test target semiconductor device by the test beam, wherein, in the irradiating with the test beam, a beam irradiation region within the test region irradiated with the test beam is changed, and a dose of the beam is nonuniform.

According to one embodiment, in the irradiating with the test beam, the beam irradiation region may be moved from a first position of the test region to a second position of the test region.

According to one embodiment, while an irradiation direction of the test beam is fixed, the test board may be moved, so that the beam irradiation region may be moved from the first position to the second position.

According to one embodiment, a direction of the movement from the first position to the second position may be perpendicular to a direction in which the irradiation of the test beam is performed left and right, or up and down.

According to one embodiment, in the method for evaluating the semiconductor device, the test board may move (continuously move) a slight distance at a constant speed, or the test board may move a predetermined distance every time after a reference time has elapsed.

According to one embodiment, in the method for evaluating the semiconductor device, the beam irradiation region may gradually expand or gradually decrease according to a distance of the test board to the test beam.

According to the embodiment described above, a beam irradiation distance may be referred to as an evaluation distance, and the beam irradiation distance may be from an exit of the test beam to a position in which a dose of the test beam is measured in advance, which is a position in which an exact dose for evaluation is known.

To achieve the technical objects described above, the present disclosure provides a system for evaluating a semiconductor device.

According to one embodiment, in the system for evaluating the semiconductor device, which is for irradiating a test target semiconductor device arranged on a test board with a test beam to measure an error value of the test target semiconductor device, while the error value of the test target semiconductor device is measured, a beam irradiation region irradiated with the test beam is changed.

According to one embodiment, the system for evaluating the semiconductor device may derive a reference error value of the test target semiconductor device from the error value of the test target semiconductor device measured while changing the beam irradiation region.

According to one embodiment, the system for evaluating the semiconductor device may derive a dose value for each irradiation region of the test beam from the error value of the test target semiconductor device measured while changing the beam irradiation region.

According to one embodiment, the beam irradiation region may continuously move, or the beam irradiation region may move every time after a reference time has elapsed.

To achieve the technical objects described above, the present disclosure provides a method for evaluating a beam characteristic.

According to one embodiment, the method for evaluating the beam characteristic includes: defining an error value that occurs when a reference test target semiconductor device is irradiated with a reference test beam as a reference error value of the reference test target semiconductor device; defining an error value that occurs when the reference test target semiconductor device is irradiated with a first test beam as a first error value; and calculating a dose value of the first test beam by using the first error value, the reference error value, and a dose value of the reference test beam.

According to one embodiment, the dose value of the first test beam may be calculated by using <Formula 1> below, wherein, in <Formula 1>, B1 is a dose value of a first test beam, E1 is a first error value, BS is a dose value of a reference test beam, and ES is a reference error value.

$$B 1 = ( E 1 \times BS ) / ES \qquad < Formula 1 >$$

According to one embodiment, the irradiating of the reference test target semiconductor device with the reference test beam to measure the reference error value of the reference test target semiconductor device may include: arranging the reference test target semiconductor device in a test region of a test board; and irradiating the test region of the test board with the reference test beam, such that a beam irradiation region within the test region irradiated with the reference test beam is changed.

To achieve the technical objects described above, the present disclosure provides a system for evaluating a beam characteristic.

According to one embodiment, the system for evaluating the beam characteristic by using a reference test target semiconductor device includes: a database configured to store a reference error value that occurs when the reference test target semiconductor device is irradiated with a reference test beam, and a dose value of the reference test beam; a test board on which the reference test target semiconductor device irradiated with a first test beam emitted from a beam source is arranged; an error value measurement unit configured to measure a first error value that occurs in the reference test target semiconductor device by the first test beam; and a beam characteristic calculation unit configured to calculate a dose value of the first test beam by using the reference error value and the dose value of the reference test beam, which are stored in the database, and the first error value.

To achieve the technical objects described above, the present disclosure provides a method for evaluating a semiconductor device.

According to one embodiment, the method for evaluating the semiconductor device includes: preparing a test board; arranging a test target semiconductor device including a reference test target semiconductor device and a non-reference test target semiconductor device in a test region of the test board; irradiating the test region of the test board with a test beam to measure an error value of the test target semiconductor device by the test beam; calculating an error correction value by using a reference error value of the reference test target semiconductor device and the measured error value of the reference test target semiconductor device; and calculating a reference error value of the non-reference test target semiconductor device from the measured error value of the non-reference test target semiconductor device by using the error correction value.

According to one embodiment, a plurality of non-reference test target semiconductor devices may be provided, the reference test target semiconductor device may be arranged in a central region of the test region, and the non-reference test target semiconductor devices may be arranged in an edge region of the test region, so that the non-reference test target semiconductor devices may surround the reference test target semiconductor device.

To achieve the technical objects described above, the present disclosure provides a system for evaluating a semiconductor device.

According to one embodiment, the system for evaluating the semiconductor device by using a reference test target semiconductor device includes: a test board having a test region on which a test target semiconductor device including the reference test target semiconductor device and a non-reference test target semiconductor device is arranged, and irradiated with a test beam emitted from a beam source; an error value measurement unit configured to measure error values of a plurality of test target semiconductor devices by the test beam; a database configured to store a reference error value of the reference test target semiconductor device; an error correction value calculation unit configured to calculate an error correction value by using the reference error value of the reference test target semiconductor device stored in the database and the error value of the reference test target semiconductor device measured by the error value measurement unit; and a reference error value calculation unit configured to calculate a reference error value of the non-reference test target semiconductor device from the error value of the non-reference test target semiconductor device measured by the error value measurement unit by using the error correction value.

To achieve the technical objects described above, the present disclosure provides a method for evaluating a semiconductor device.

According to one embodiment, the method for evaluating the semiconductor device includes: preparing a first test board on which a reference test target semiconductor device is arranged; preparing a second test board on which a non-reference test target semiconductor device is arranged such that the second test board is spaced apart from the first test board to overlap the first test board; irradiating the first test board and the second test board, which are spaced apart from each other to overlap each other, with a test beam to measure an error value of the reference test target semiconductor device and an error value of the non-reference test target semiconductor device by the test beam; calculating an error correction value by using a reference error value of the reference test target semiconductor device and the measured error value of the reference test target semiconductor device; and calculating a reference error value of the non-reference test target semiconductor device from the measured error value of the non-reference test target semiconductor device by using a distance between the first test board and the second test board and the error correction value.

According to one embodiment, the non-reference test target semiconductor device may be arranged together with the reference test target semiconductor device in the first test board, or only the reference test target semiconductor device may be arranged in the first test board.

To achieve the technical objects described above, the present disclosure provides a system for evaluating a semiconductor device.

According to one embodiment, the system for evaluating the semiconductor device by using a reference test target semiconductor device includes: a first test board on which the reference test target semiconductor device is arranged; a second test board on which a non-reference test target semiconductor device is arranged, and spaced apart from the first test board to overlap the first test board; a database configured to store a reference error value of the reference test target semiconductor device; an error value measurement unit configured to measure error values of the reference test target semiconductor device and the non-reference test target semiconductor device by a test beam emitted from a beam source to irradiate the first test board and the second test board, which are spaced apart from each other to overlap each other; an error correction value calculation unit configured to calculate an error correction value by using the reference error value of the reference test target semiconductor device stored in the database and the error value of the reference test target semiconductor device measured by the error value measurement unit; and a reference error value calculation unit configured to calculate a reference error value of the non-reference test target semiconductor device from the error value of the non-reference test target semiconductor device measured by the error value measurement unit by using a distance between the first test board and the second test board and the error correction value.

To achieve the technical objects described above, the present disclosure provides a system for evaluating a semiconductor device.

According to one embodiment, the system for evaluating the semiconductor device includes: a test board on which a test target semiconductor device irradiated with a test beam emitted from a beam source is arranged; a beam characteristic control board disposed between the test board and the beam source, and through which the test beam is transmitted; and an error value measurement unit configured to measure an error value that occurs in the test target semiconductor device by the test beam transmitted through the beam characteristic control board so as to irradiate the test target semiconductor device.

According to one embodiment, a beam characteristic control material may be disposed on the beam characteristic control board, the test beam may be transmitted through the beam characteristic control material so as to irradiate the test target semiconductor device, and a dose and energy of the test beam transmitted through the beam characteristic control material may be adjusted.

According to one embodiment, a plurality of beam characteristic control materials may be provided, and thicknesses and physical properties of the beam characteristic control materials may be different from each other, or the thickness of the beam characteristic control material may vary according to a region.

According to one embodiment, the beam characteristic control board may continuously move (e.g., move a slight distance at a constant speed), or the beam characteristic control board may move every time after a reference time has elapsed (e.g., move in a stepwise or step-like arrangement on a chip basis, a cell basis, or a predetermined grid basis).

### Advantageous Effects

According to an embodiment of the present disclosure, a test target semiconductor device may be arranged in a test region of a test board, and the test region of the test board may be irradiated with a test beam to measure an error value of the test target semiconductor device by the test beam.

While the error value of the test target semiconductor device is measured, a beam irradiation region irradiated with the test beam may be changed, so that a plurality of test target semiconductor devices can be irradiated with the test beam at the same dose that is substantially quantifiable. Accordingly, reference error values of the test target semiconductor devices can be easily defined, and other test target semiconductor devices can be easily evaluated with high reliability by using the test target semiconductor devices in which the reference error values are defined.

In addition, the test target semiconductor devices can be simultaneously evaluated, an evaluation time can be shortened, and accuracy of an evaluation result can be improved.

In addition, according to an embodiment of the present disclosure, a plurality of test target semiconductor devices including a reference test target semiconductor device and a non-reference test target semiconductor device may be arranged in a test region of a test board, and the test region of the test board may be irradiated with a test beam to measure error values of the test target semiconductor devices by the test beam. Thereafter, an error correction value may be calculated by using a reference error value of the reference test target semiconductor device and the measured error value of the reference test target semiconductor device, and a reference error value of the non-reference test target semiconductor device may be calculated from the measured error value of the non-reference test target semiconductor device by using the error correction value.

A fluctuation of a difference in error value of the non-reference test target semiconductor device according to a dose of the test beam can be compensated for, so that the reference error value of the non-reference test target semiconductor device can be easily obtained, and thus evaluation reliability for the non-reference test target semiconductor device can be improved.

In addition, a beam characteristic control board disposed between the test board and a beam source configured to perform the irradiation of the test beam, and through which the test beam is transmitted may be provided. An error value that occurs in the test target semiconductor device may be measured by the test beam transmitted through the beam characteristic control board so as to irradiate the test target semiconductor device, so that a sensitive region, an error cross section for each energy, and Bragg peak position information according to a characteristic of the test beam can be determined, and thus evaluation reliability for the test target semiconductor device can be improved.

### BRIEF DESCRIPTION OF THE DRAWINGS

FIG. 1 is a view for describing a system for evaluating a semiconductor device according to an embodiment of the present disclosure.

FIG. 2 is a view for describing a variation in dose according to an evaluation distance of a test beam used in the system for evaluating the semiconductor device according to the embodiment of the present disclosure.

FIG. 3 is a view for describing a difference in reference error value of a test target semiconductor device used in the system for evaluating the semiconductor device according to the embodiment of the present disclosure.

FIG. 4 is a view for describing a difference in dose for each region of the test beam used in the system for evaluating the semiconductor device according to the embodiment of the present disclosure.

FIG. 5 is a view for describing a difference in error value according to characteristics of the test beam and the test target semiconductor device used in the system for evaluating the semiconductor device according to the embodiment of the present disclosure.

FIG. 6 is a flowchart for describing a method for evaluating a semiconductor device according to an embodiment of the present disclosure.

FIG. 7 is a view for describing a process of changing a beam irradiation region in the method for evaluating the semiconductor device and the system for evaluating the semiconductor device according to the embodiment of the present disclosure.

FIG. 8 is a view for describing examples of arrangement of a plurality of test target semiconductor devices in the method for evaluating the semiconductor device and the system for evaluating the semiconductor device according to the embodiment of the present disclosure.

FIG. 9 is a view for describing a process of moving the beam irradiation region in the method for evaluating the semiconductor device and the system for evaluating the semiconductor device according to the embodiment of the present disclosure, in which a reference error value of the semiconductor device and a reference dose value for each region of the test beam may be determined by deriving the reference error value through an evaluation result of the semiconductor device.

FIG. 10 is a view for describing the beam irradiation region and a test region in the method for evaluating the semiconductor device and the system for evaluating the semiconductor device according to the embodiment of the present disclosure.

FIG. 11 is a view for describing an overlapping process of the beam irradiation region and the test region of FIG. 10.

FIGS. 12 to 15 are graphs showing an error value of the test target semiconductor device measured according to the method for evaluating the semiconductor device according to the embodiment of the present disclosure.

FIG. 16 is a view for describing a stepwise overlapping process and a scanning process in the method for evaluating the semiconductor device and the system for evaluating the semiconductor device according to the embodiment of the present disclosure.

FIG. 17 is a graph showing an error value for each device according to stepwise overlapping in the method for evaluating the semiconductor device and the system for evaluating the semiconductor device according to the embodiment of the present disclosure.

FIG. 18 is a view for describing the scanning process in the method for evaluating the semiconductor device and the system for evaluating the semiconductor device according to the embodiment of the present disclosure.

FIG. 19 is a graph showing an error value for each device according to the scanning process in the method for evaluating the semiconductor device and the system for evaluating the semiconductor device according to the embodiment of the present disclosure.

FIGS. 20 and 21 are graphs for describing sameness of a dose of the test beam with which the test target semiconductor device is irradiated in the method for evaluating the semiconductor device and the system for evaluating the semiconductor device according to the embodiment of the present disclosure.

FIG. 22 is a view for describing an internal structure of the test target semiconductor device according to the embodiment of the present disclosure.

FIG. 23 is a view for describing a process of applying the method for evaluating the semiconductor device according to the embodiment of the present disclosure to the test target semiconductor device having the internal structure of FIG. 22.

FIGS. 24 and 25 are views for describing the system for evaluating the semiconductor device according to the embodiment of the present disclosure.

FIG. 26 is a view for describing the difference in dose for each region of the test beam used in the system for evaluating the semiconductor device according to the embodiment of the present disclosure.

FIG. 27 is a flowchart for describing a method for evaluating a beam characteristic by using a reference semiconductor device according to an embodiment of the present disclosure.

FIG. 28 is a view for describing the method for evaluating the beam characteristic by using the reference semiconductor device and a method for evaluating a reference error value of a reference semiconductor device according to the embodiment of the present disclosure.

FIG. 29 is a block diagram for describing a system for evaluating a beam characteristic by using a reference semiconductor device according to an embodiment of the present disclosure.

FIG. 30 is a flowchart for describing a method for calculating a reference error value of a reference test target semiconductor device in the method for evaluating the semiconductor device according to the embodiment of the present disclosure.

FIG. 31 is a view for describing a process of moving the beam irradiation region in the method for calculating the reference error value of the test target semiconductor device in the method for evaluating the semiconductor device according to the embodiment of the present disclosure.

FIG. 32a is a view for describing the overlapping process of the beam irradiation region and the test region of FIG. 31.

FIG. 32b is a view for describing evaluation of a dose by using one test target semiconductor device in the method for evaluating the semiconductor device according to the embodiment of the present disclosure.

FIG. 33 is a graph showing an error value of the reference test target semiconductor device measured according to the method for calculating the reference error value of the reference test target semiconductor device in the method for evaluating the semiconductor device according to the embodiment of the present disclosure.

FIG. 34 is a flowchart for describing a method for evaluating a semiconductor device by using a reference semiconductor device according to a first embodiment of the present disclosure.

FIG. 35 is a view for describing the method for evaluating the semiconductor device by using the reference semiconductor device according to the first embodiment of the present disclosure.

FIG. 36 is a block diagram for describing a system for evaluating a semiconductor device by using a reference semiconductor device according to a first embodiment of the present disclosure.

FIG. 37 is a flowchart for describing a method for evaluating a semiconductor device by using a reference semiconductor device according to a second embodiment of the present disclosure.

FIGS. 38 to 41 are views for describing the method for evaluating the semiconductor device by using the reference semiconductor device according to the second embodiment of the present disclosure.

FIG. 42 is a block diagram for describing a system for evaluating a semiconductor device by using a reference semiconductor device according to a second embodiment of the present disclosure.

FIG. 43 is a view for describing a method for evaluating a semiconductor device by using a beam characteristic control board according to an embodiment of the present disclosure.

FIG. 44 is a view for describing an arrangement of a beam characteristic control material in the beam characteristic control board according to the embodiment of the present disclosure.

FIGS. 45 and 46 are views for describing a structure of the beam characteristic control material in the beam characteristic control board according to the embodiment of the present disclosure.

### MODE FOR INVENTION

Hereinafter, exemplary embodiments of the present invention will be described in detail with reference to the accompanying drawings. However, the technical idea of the present invention is not limited to the embodiments described herein, but may be embodied in different forms. The embodiments introduced herein are provided to sufficiently deliver the idea of the present invention to those skilled in the art so that the disclosed contents may become thorough and complete.

In addition, although the terms such as first, second, and third have been used to describe various elements in various embodiments of the present disclosure, the elements are not limited by the terms. The terms are used only to distinguish one element from another element. Therefore, an element mentioned as a first element in one embodiment may be mentioned as a second element in another embodiment. The embodiments described and illustrated herein include their complementary embodiments, respectively. Further, the term “and/or” used in the present disclosure is used to include at least one of the elements enumerated before and after the term.

As used herein, an expression in a singular form includes a meaning of a plural form unless the context clearly indicates otherwise. Further, the terms such as “including” and “having” are intended to designate the presence of features, numbers, steps, elements, or combinations thereof described herein, and shall not be construed to preclude any possibility of the presence or addition of one or more other features, numbers, steps, elements, or combinations thereof. Further, in the following description of the present invention, detailed descriptions of known functions or configurations incorporated herein will be omitted when they may make the gist of the present invention unnecessarily unclear.

According to the present disclosure, “beam” may include a radiation and/or radiation particles, which may be interpreted as including radiation particles such as alpha particles, neutrons, protons, heavy ions, gamma rays, and X-rays, and an error that occurs in the test target semiconductor device according to the present disclosure may be interpreted to have a general meaning that mainly includes a soft error such as a single bit upset (SBU), a multi bit upset (MBU), and a multi cell upset (MCU) among single event upsets (SEUs).

In addition, it is obvious that an entity that manufactures and sells a system for evaluating a semiconductor device described in the present disclosure and an entity that performs a method for evaluating a semiconductor device described in the present disclosure may be different from each other.

In addition, it is obvious that a test target semiconductor device described in the present disclosure may include various analog and/or digital semiconductor devices that are not specified in the present disclosure, such as an SRAM, a flash memory, a DRAM, a cache memory, a logic IC, an image sensor device, a display device, a power IC, an RF IC, an SSD, an RRAM, a PRAM, and an MRAM.

In addition, it is obvious to those skilled in the art that a dose described in the present disclosure may be interpreted to have a meaning including the number of particles with which a given region is irradiated during a unit time, or the number of particles with which a unit region is irradiated during a given time, and may be interpreted to have a meaning including a flux.

General semiconductor device evaluation equipment may be used for evaluating various defects that occur during a production process. Meanwhile, according to an embodiment of the present disclosure, an evaluation method and an evaluation system for evaluating defects caused by a radiation in a semiconductor device that has passed all evaluation processes and operates normally after production may be provided.

In addition, a system for evaluating a semiconductor device, which will be described below, may further include a control region including a computer apparatus and software in addition to a beam irradiation region.

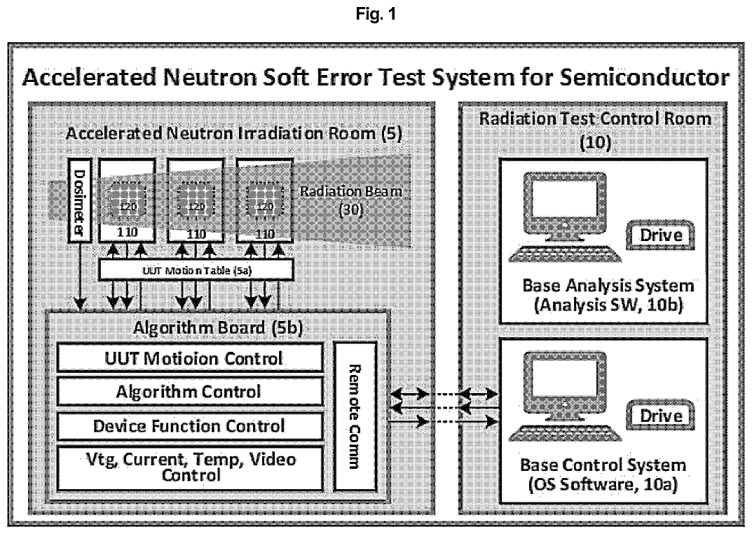

A method for evaluating a radiation of a semiconductor device and a system for evaluating a radiation of a semiconductor device according to an embodiment of the present disclosure will be described with reference to FIGS. 1 to 25.

FIG. 1 is a view for describing a system for evaluating a semiconductor device according to an embodiment of the present disclosure.

Referring to FIG. 1, according to an embodiment of the present disclosure, a system for evaluating a semiconductor device may include a beam irradiation region 5 and a control region 10.

A test board 110 on which a plurality of test target semiconductor devices 120 are arranged may be provided in the beam irradiation region 5, and the test target semiconductor devices 120 of the test board 110 may be irradiated with a test beam 130. An error may occur in the test target semiconductor devices 120 by the test beam 130.

A UUT motion table 5a in the beam irradiation region 5 may control a movement of the test board 110 to change a region irradiated with the test beam 130, as will be described below.

An algorithm board 5b may include a UUT motion control unit, a semiconductor function control unit, an algorithm control unit, and a voltage, current, temperature, and video control unit. The algorithm board 5b may measure and count an error that occurs in the test target semiconductor devices 120 and transmit an error value to a base control system 10a of the control region 10 through a remote communication unit, and the base control system 10a may control operations of the UUT motion control unit, the semiconductor function control unit, the algorithm control unit, and the voltage, current, temperature, and video control unit of the algorithm board 5b through the remote communication unit.

A base analysis system 10b of the control region 10 may analyze error values of the test target semiconductor devices 120 received from the base control system 10a to define/measure/calculate reference error values of the test target semiconductor devices 120.

In other words, according to the embodiment of the present disclosure, the system for evaluating the semiconductor device may analyze and store an evaluation result of the test target semiconductor device 120.

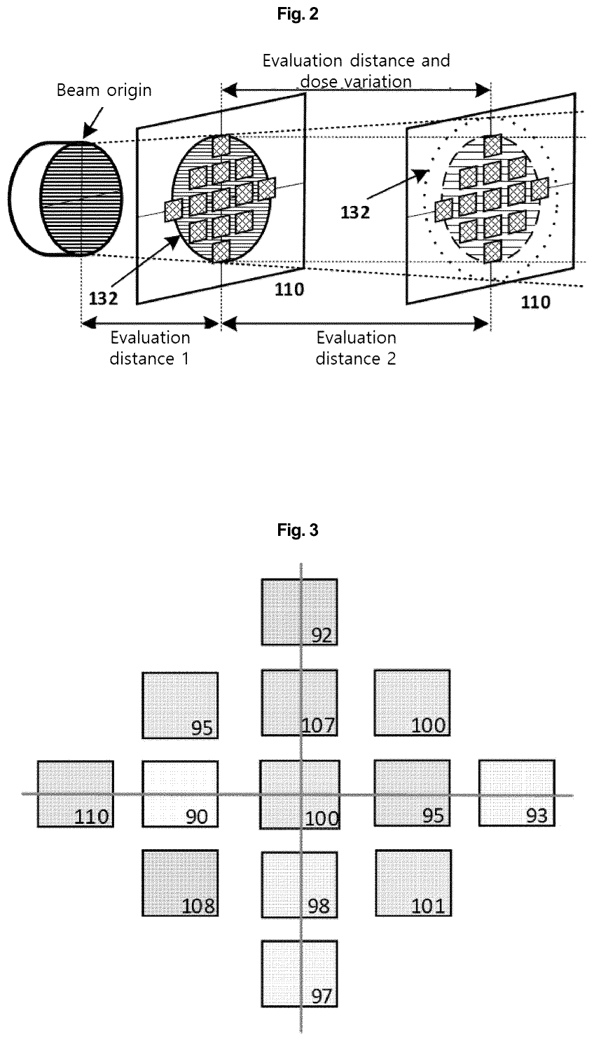

In general, a dose of the test beam 130 with which the test target semiconductor device 120 is irradiated may vary according to a beam source, a difference in dose may occur according to a distance between the beam source and the test target semiconductor device 120, a difference in dose may occur for each region in the beam irradiation region irradiated with the test beam 130, and the test target semiconductor device 120 may have a reference error value and an error ratio according to a dose by which the irradiation is performed, so that the reference error value of the test target semiconductor device 120 may not be easily defined. Hereinafter, the above configuration will be described in more detail with reference to FIGS. 2 to 5.

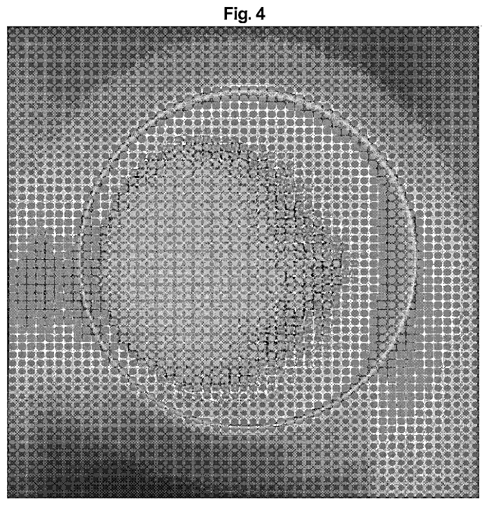

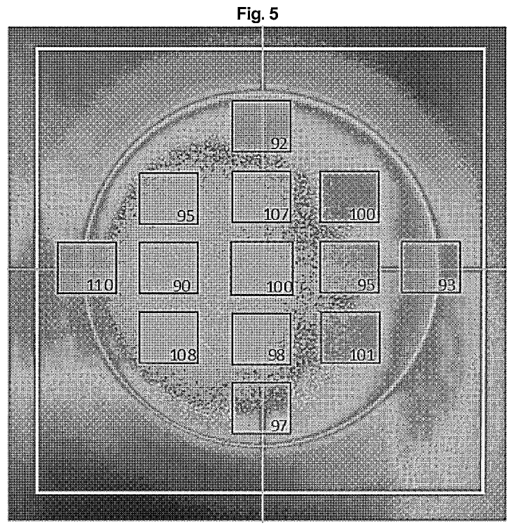

FIG. 2 is a view for describing a variation in dose according to an evaluation distance of a test beam used in the system for evaluating the semiconductor device according to the embodiment of the present disclosure, FIG. 3 is a view for describing a difference in reference error value of a test target semiconductor device used in the system for evaluating the semiconductor device according to the embodiment of the present disclosure, FIG. 4 is a view for describing a difference in dose for each region of the test beam used in the system for evaluating the semiconductor device according to the embodiment of the present disclosure, and FIG. 5 is a view for describing a difference in error value according to characteristics of the test beam and the test target semiconductor device used in the system for evaluating the semiconductor device according to the embodiment of the present disclosure.

Referring to FIG. 2, in an overall region irradiated with the test beam 130 by the beam source, a beam irradiation region 132 may be defined on the test board 110. However, as shown in FIG. 2, when the test board 110 is located at a position relatively close to the beam source, and when the test board 110 is located at a position relatively far from the beam source, the beam irradiation region 132 may vary. In detail, as shown in FIG. 2, when a distance between the beam source and the test board 110 is relatively short, the beam irradiation region 132 may be relatively narrow, and a dose of the test beam 132 with which a reference region of the beam irradiation region 132 is irradiated may be relatively high. Meanwhile, as shown in FIG. 2, when the distance between the beam source and the test board 110 is relatively long, the beam irradiation region 132 may be relatively wide, and the dose of the test beam 132 with which the reference region of the beam irradiation region 132 is irradiated may be relatively low.

Referring to FIG. 3, when the test target semiconductor devices are arranged on the test board, each of the test target semiconductor devices may have a reference error value and an error ratio for the test beam. In other words, sensitivities of the test target semiconductor devices to the test beam may be different from each other without being identical to each other, so that, even in an environment where the test target semiconductor devices are irradiated with the test beam of the same dose, as shown in FIG. 3, the test target semiconductor devices may have mutually different error values and error ratios. FIG. 3 shows a ratio to a reference error value and an error ratio of a test target semiconductor device that is located at a center among the test target semiconductor devices when assuming that the reference error value and the error ratio of the test target semiconductor device that is located at the center are 100.

Referring to FIG. 4, the difference in dose may occur for each region in the beam irradiation region irradiated with the test beam. In other words, as shown in FIG. 4, a relatively dark region (a gray or black region in FIG. 4) may be a region irradiated with a relatively small dose of the test beam, and a relatively pale region (a region close to white in FIG. 4) may be a region irradiated with a relatively high dose of the test beam.

Referring to FIG. 5, the test target semiconductor devices described with reference to FIG. 3 may be arranged in the beam irradiation region described with reference to FIG. 4, in which the difference in dose may occur even in the beam irradiation region irradiated with the test beam, and the sensitivities of the test target semiconductor devices to the test beam may be different from each other so that the test target semiconductor devices may have reference error values and error ratios.

In conclusion, a beam profile of the test beam may not be uniform within the beam irradiation region, the difference in dose may occur in the beam irradiation region according to the distance between the beam source and the test board, and a difference in sensitivity of the test target semiconductor devices to the test beam may occur. For this reason, there may be a limitation in accurate measurement of error values and error ratios of the test target semiconductor devices by the test beam, and, in order to solve such a problem, it may be necessary to define reference error values and reference error ratios of the test target semiconductor devices.

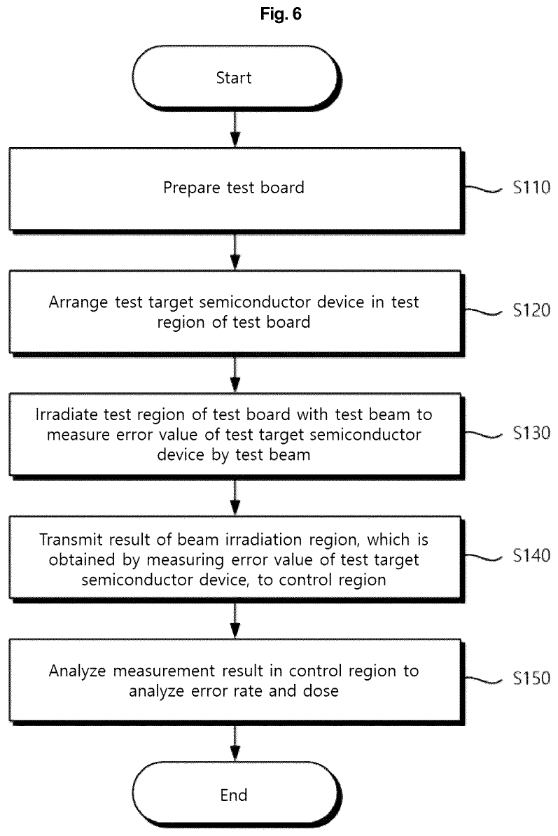

FIG. 6 is a flowchart for describing a method for evaluating a semiconductor device according to an embodiment of the present disclosure.

Referring to FIG. 6, a test board may be prepared (S110), a plurality of test target semiconductor devices may be arranged in a test region of the test board (S120), and the test region of the test board may be irradiated with a test beam to measure error values of the test target semiconductor devices by the test beam (S130).

In this case, the beam irradiation region within the test region, which is irradiated with the test beam, may be changed. In other words, the beam irradiation region within the test region may be moved, expanded, and/or contracted, so that the test target semiconductor devices may be irradiated with the test beam at the same dose, and, as a result, the reference error values and the error ratios of the test target semiconductor devices may be determined.

In order to analyze the reference error value and the error ratio, a result of the beam irradiation region, which is obtained by measuring an error value of the test target semiconductor device may be transmitted to the control region 10 described with reference to FIG. 1 (S140).

Thereafter, the measurement result may be analyzed by the base control system 10a and the base analysis system 10b of the control region 10 to analyze an error rate and a dose. In other words, the reference error value and the error ratio may be analyzed.

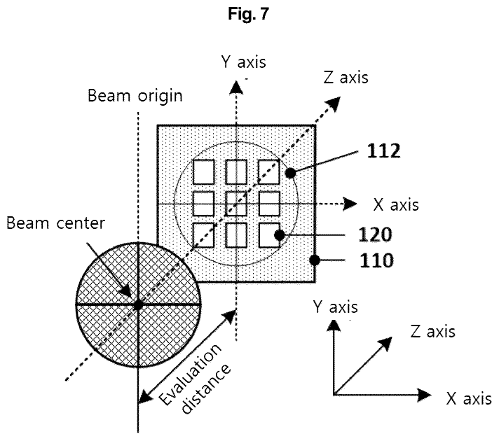

FIG. 7 is a view for describing a process of changing a beam irradiation region in the method for evaluating the semiconductor device and the system for evaluating the semiconductor device according to the embodiment of the present disclosure.

Referring to FIG. 7, the test target semiconductor devices 120 may be arranged in the test region 112 of the test board 110, and the test region 112 may be irradiated with the test beam.

As shown in FIG. 7, three axes (an X axis, a Y axis, and a Z axis) may be defined, the X axis and the Y axis may be parallel to a top surface and a side surface of the test board 110, respectively (the X axis may be parallel to the top surface, and the Y axis may be parallel to the side surface), and the Z axis may be parallel to a direction in which the test board 110 is irradiated with the test beam (i.e., an evaluation distance).

According to one embodiment, the beam irradiation region may be moved from a first position of the test region 112 to a second position of the test region 112, and a direction of the movement from the first position to the second position may be parallel to the X axis or parallel to the Y axis. In detail, while an irradiation direction of the test beam is fixed, the test board 110 may be moved in a direction parallel to the X axis or moved in a direction parallel to the Y axis, so that the beam irradiation region within the test region 112 may be moved. Alternatively, while the test board 110 is fixed, the irradiation direction of the test beam may be moved in the direction parallel to the X axis or moved in the direction parallel to the Y axis, so that the beam irradiation region within the test region 112 may be moved. In other words, while the test board 110 is fixed, a collimator of the test beam may be moved in an X axis direction and/or a Y axis direction in the beam region.

Alternatively, according to another embodiment, as described above, the beam irradiation region may be moved from the first position of the test region 112 to the second position of the test region 112, such that the direction of the movement from the first position to the second position may be parallel to the Z axis. In detail, while the beam source configured to perform the irradiation of the test beam is fixed, the test board 110 may be moved in a direction parallel to the Z axis, so that the beam irradiation region within the test region 112 may be expanded or contracted. Alternatively, while the test board 110 is fixed, the beam source may be moved in the direction parallel to the Z axis, so that the beam irradiation region within the test region may be expanded or contracted. In other words, for example, upon accelerated alpha evaluation, AM241 having a coin size, which is a particle source of alpha particles, may be moved in the X axis direction and/or the Y axis direction. That is, the distance between the beam source and the test board 110 may be adjusted, so that the beam irradiation region within the test region 112 may be changed.

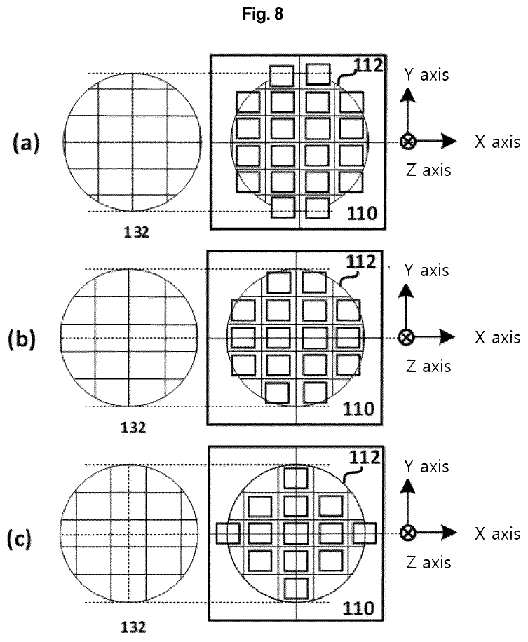

FIG. 8 is a view for describing examples of arrangement of a plurality of test target semiconductor devices in the method for evaluating the semiconductor device and the system for evaluating the semiconductor device according to the embodiment of the present disclosure.

Referring to FIG. 8, a plurality of test target semiconductor devices may be arranged in the test region 112 matching the beam irradiation region 132. In detail, as shown in (a) of FIG. 8, within the test region 112 divided into a plurality of grids, the test target semiconductor devices may be arranged in each of the grids. Alternatively, as shown in (b) of FIG. 8, unlike (a) of FIG. 8, the test target semiconductor devices may be located inside the grid while being arranged on a central line at a center of the test region 112 in the X axis direction. Alternatively, as shown in (c) of FIG. 8, the test target semiconductor devices may be located inside the grid while being arranged based on a line in which central lines at centers of the X axis and the Y axis, respectively, intersect each other.

It is obvious that, the test target semiconductor devices may be arranged in various forms on the test board 110 in addition to the arrangements shown in (a) to (c) of FIG. 8, and the technical idea of the present disclosure is not limited by the form and a shape in which the test target semiconductor devices are arranged on the test board 110.

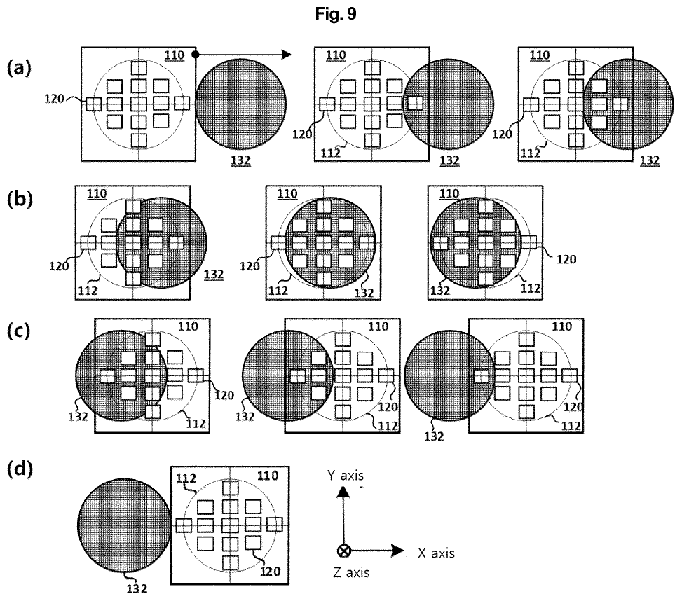

FIG. 9 is a view for describing a process of moving the beam irradiation region in the method for evaluating the semiconductor device and the system for evaluating the semiconductor device according to the embodiment of the present disclosure.

Referring to FIG. 9, the test target semiconductor devices 120 may be arranged on the test board 110, and the beam irradiation region 132 irradiated with the test beam may be provided.

Although the test board 110 has been described with reference to FIG. 9 as being moved in the direction parallel to the X axis of FIG. 7, embodiments are not limited thereto, and it is obvious to those skilled in the art that the test board 110 may be moved in the direction parallel to the Y axis of FIG. 7, or the test board 110 may be moved in the direction parallel to the Z axis of FIG. 7. In addition, although the test board 110 has been described as being moved, embodiments are not limited thereto, and it is obvious that the test board 110 may be fixed, and the beam source configured to perform the irradiation of the test beam may be moved. In addition, the test board 110 and the beam source may be moved simultaneously.

In addition, in the description with reference to FIG. 9, it is obvious to those skilled in the art that the test target semiconductor devices may be arranged in a form and an arrangement that are different from the form and the arrangement of the test target semiconductor devices arranged on the test board 110.

In addition, although the test target semiconductor devices have been described with reference to FIG. 9 as being arranged on the test board 110, embodiments are not limited thereto, and it is obvious to those skilled in the art that one test target semiconductor device may be arranged on the test board 110. Alternatively, it is obvious to those skilled in the art that the test target semiconductor devices may be arranged on the test board 110 along the X axis, the Y axis, or the X and Y axes.

Next, referring to FIG. 9, as shown in (a) to (d) of FIG. 9, the beam irradiation region 132 may be located outside the test board 110, and, as the beam irradiation region 132 gradually moves, the rightmost test target semiconductor device 120 and the beam irradiation region 132 may overlap each other so that the rightmost test target semiconductor device 120 may be irradiated with the test beam, and sequentially, the test target semiconductor devices 120 located on a left side of the rightmost test target semiconductor device 120 may also be irradiated with the test beam. Finally, the leftmost test target semiconductor device 120 and the beam irradiation region 132 may overlap each other so that the leftmost test target semiconductor device 120 may be irradiated with the test beam, and the irradiation for the test target semiconductor devices 120 with the test beam may be terminated. FIG. 9 shows the irradiation of the test beam being performed nine times, and the technical idea according to the embodiment of the present disclosure is not limited thereto.

As described above, while the test target semiconductor devices 120 are irradiated with the test beam, that is, while the beam irradiation region 132 overlaps the test target semiconductor devices 120, errors that occur in the test target semiconductor devices 120 may be measured and counted. The errors that occur in the test target semiconductor devices 120 may be measured, counted, and analyzed through the algorithm board, the base control system 10a, and the base analysis system 10b of the system for evaluating the semiconductor device described with reference to FIG. 1. In addition, the same effect may be implemented in the evaluation of the semiconductor device through a scanning process, which will be described below.

According to one modified example, as described with reference to FIG. 9, after the irradiation of the test beam is performed from the rightmost test target semiconductor device 120 to the leftmost test target semiconductor device 120, the irradiation of the test beam may be performed again from the leftmost test target semiconductor device 120 to the rightmost test target semiconductor device 120.

As described above, when a process of irradiating all of the test target semiconductor devices 120 with the test beam is defined as a unit cycle, the unit cycle may be performed once or a plurality of times, and the errors that occur in the test target semiconductor devices 120 may be measured and counted while the unit cycle is performed once or a plurality of times.

In addition, as in one modified example described above, when the unit cycle is performed a plurality of times, directions in which the test beam is moved may be the same as or different from each other. In other words, for example, when the unit cycle is performed twice, as described with reference to FIG. 9, after the test beam is moved from the rightmost test target semiconductor device 120 to the leftmost test target semiconductor device 120, the test beam may be moved from the leftmost test target semiconductor device 120 to the rightmost test target semiconductor device 120. That is, the test board 110 may be moved in a +direction (a movement from left to right) and a −direction (a movement from right to left) in the X axis direction, so that the unit cycle may be performed.

Alternatively, for another example, when the unit cycle is performed twice, in a first unit cycle, the test board 110 may be moved in the +direction or the −direction along the X axis, and, in a second unit cycle, the test board 110 may be moved in a +direction (a movement from bottom to top) or a −direction (a movement from top to bottom) along the Y axis.

Alternatively, for still another example, when the unit cycle is performed twice, in the first unit cycle, the test board 110 may be moved in the +direction or the −direction along the X axis, and, in the second unit cycle, the test board 110 may be moved in a +direction (a movement from paper to a viewer) or a −direction (a movement from the viewer to the paper) along the Z axis.

Alternatively, for yet another example, when the unit cycle is performed twice, in the first unit cycle, the test board 110 may be moved in the +direction or the −direction along the Y axis, and, in the second unit cycle, the test board 110 may be moved in the +direction or the −direction along the Z axis.

As described above, when the unit cycle is performed a plurality of times, directions in which the test board 110 is irradiated with the test beam may be the same as or different from each other in a plurality of unit cycles.

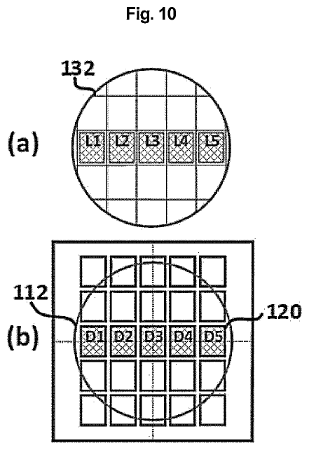

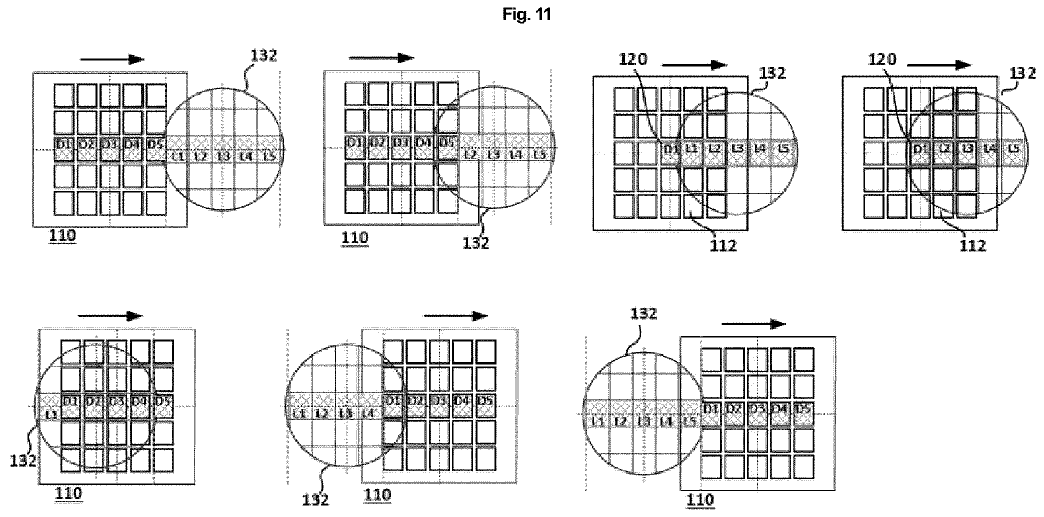

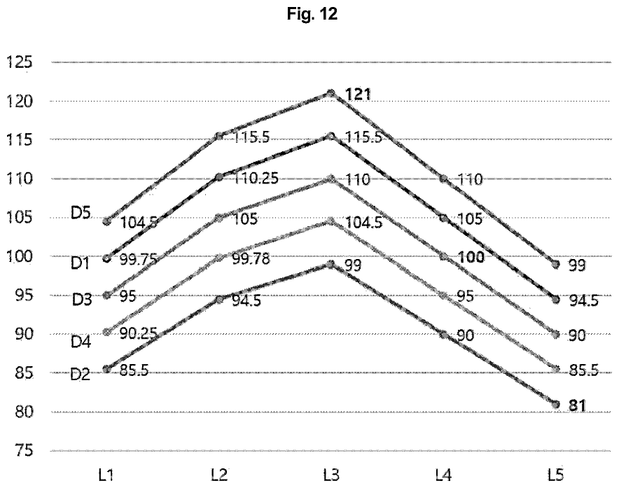

FIG. 10 is a view for describing the beam irradiation region and a test region in the method for evaluating the semiconductor device and the system for evaluating the semiconductor device according to the embodiment of the present disclosure, FIG. 11 is a view for describing an overlapping process of the beam irradiation region and the test region of FIG. 10, and FIGS. 12 to 15 are graphs showing an error value of the test target semiconductor device measured according to the method for evaluating the semiconductor device according to the embodiment of the present disclosure.

Referring to FIGS. 10 and 11, as shown in (a) of FIG. 10, the beam irradiation region irradiated with the test beam may be partitioned into a plurality of grids, and regions L1 to L5 may be defined in the beam irradiation region.

In addition, as shown in (b) of FIG. 10, the test region of the test board may also be partitioned into a plurality of grids to correspond to the beam irradiation region, and a plurality of test target semiconductor devices D1 to D5 may be arranged in the test region.

Thereafter, as shown in FIG. 11, D5 may overlap L1, D4, D3, D2, and D1 may sequentially overlap L1, and finally, D1 may overlap L5, so that the unit cycle may be terminated.

As described above, during the unit cycle, error values of the test target semiconductor devices D1 to D5 for L1 to L5 may be measured and counted.

For example, when a difference in dose among L1 to L5 compared with an average value of a total dose is as shown in <Table 1> below, and a difference in reference error value of D1 to D5 is as shown in <Table 2> below, an error value may be measured as shown in <Table 3> below and FIG. 12.

As shown in <Table 3> below and FIG. 12, the measured error value had a maximum value of 121 when D5 is located at L3, and the measured error value had a minimum value of 81 when D2 is located at L5. Among a plurality of error values, when 100, which is a value adjacent to a medium value, is used as a reference, an error value of D3 located at L4 may be defined as a reference error value of D3, and reference error values of D1, D2, D4, and D5 may be defined as 105, 90, 95, and 110, which are relative ratios to the reference error value of D3, at a position of L4 in which the reference error value of D3 is defined.

TABLE 1

| L1 | L2 | L3 | L4 | L5 |
|---|---|---|---|---|
| −5% | +5% | +10% | 0% | −10% |

TABLE 2

| D1 | D2 | D3 | D4 | D5 |
|---|---|---|---|---|
| 105 | 90 | 100 | 95 | 110 |

TABLE 3

| | L1 | L2 | L3 | L4 | L5 |
|---|---|---|---|---|---|
| D1 | 99.75 | 110.25 | 115.5 | 105 | 94.5 |
| D2 | 85.5 | 94.5 | 99 | 90 | 81 |
| D3 | 95 | 105 | 110 | 100 | 90 |
| D4 | 90.25 | 99.78 | 104.5 | 95 | 85.5 |
| D5 | 104.5 | 115.5 | 121 | 110 | 99 |

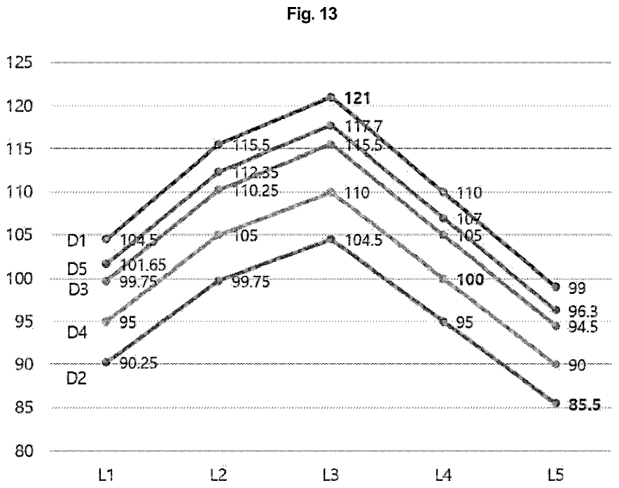

For another example, when a difference in dose among L1 to L5 is as shown in <Table 1>, and a difference in error value of D1 to D5 is as shown in <Table 4> below, an error value may be measured as shown in <Table 5> below and FIG. 13.

As shown in <Table 5> below and FIG. 13, the measured error value had a maximum value of 121 when D1 is located at L3, and the measured error value had a minimum value of 85.5 when D2 is located at L5. Among a plurality of error values, when 100, which is a value adjacent to a medium value, is used as a reference, an error value of D4 located at L4 may be defined as a reference error value of D4, and reference error values of D1, D2, D3, and D5 may be defined as 110, 95, 105, and 107, which are relative ratios to the reference error value of D4, at a position of L4 in which the reference error value of D4 is defined.

TABLE 4

| D1 | D2 | D3 | D4 | D5 |
|---|---|---|---|---|
| 110 | 95 | 105 | 100 | 107 |

TABLE 5

| | L1 | L2 | L3 | L4 | L5 |
|---|---|---|---|---|---|
| D1 | 104.5 | 115.5 | 121 | 110 | 99 |
| D2 | 90.25 | 99.75 | 104.5 | 95 | 85.5 |
| D3 | 99.75 | 110.25 | 115.5 | 105 | 94.5 |
| D4 | 95 | 105 | 110 | 100 | 90 |
| D5 | 101.65 | 112.35 | 117.7 | 107 | 96.3 |

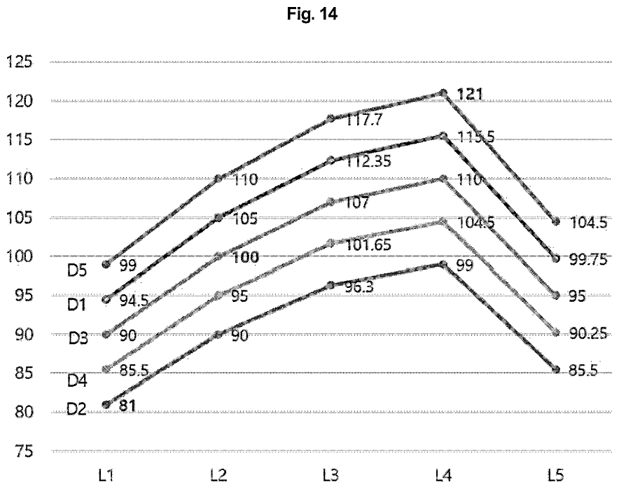

For still another example, when a difference in dose among L1 to L5 is as shown in <Table 6> below, and a difference in error value of D1 to D5 is as shown in <Table 2>, an error value may be measured as shown in <Table 7> below and FIG. 14.

As shown in <Table 7> below and FIG. 14, the measured error value had a maximum value of 121 when D5 is located at L4, and the measured error value had a minimum value of 81 when D2 is located at L1. Among a plurality of error values, when 100, which is a value adjacent to a medium value, is used as a reference, an error value of D3 located at L2 may be defined as a reference error value of D3, and reference error values of D1, D2, D4, and D5 may be defined as 105, 90, 95, and 110, which are relative ratios to the reference error value of D3, at a position of L2 in which the reference error value of D3 is defined.

TABLE 6

| L1 | L2 | L3 | L4 | L5 |
|---|---|---|---|---|
| −10% | 0% | 7% | 10% | −5% |

TABLE 7

| | L1 | L2 | L3 | L4 | L5 |
|---|---|---|---|---|---|
| D1 | 94.5 | 105 | 112.35 | 115.5 | 99.75 |
| D2 | 81 | 90 | 96.3 | 99 | 85.5 |
| D3 | 90 | 100 | 107 | 110 | 95 |
| D4 | 85.5 | 95 | 101.65 | 104.5 | 90.25 |
| D5 | 99 | 110 | 117.7 | 121 | 104.5 |

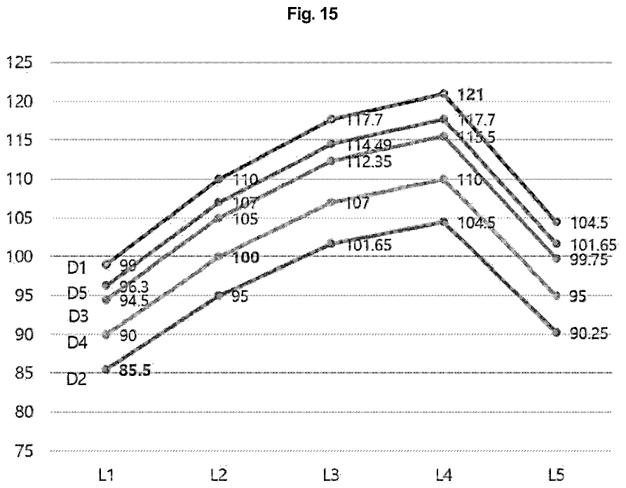

For yet another example, when a difference in dose among L1 to L5 is as shown in <Table 6>, and a difference in error value of D1 to D5 is as shown in <Table 4>, an error value may be measured as shown in <Table 8> below and FIG. 15.

As shown in <Table 8> below and FIG. 15, the measured error value had a maximum value of 121 when D1 is located at L4, and the measured error value had a minimum value of 85.5 when D2 is located at L1. Among a plurality of error values, when 100, which is a value adjacent to a medium value, is used as a reference, an error value of D4 located at L2 may be defined as a reference error value of D4, and reference error values of D1, D2, D3, and D5 may be defined as 110, 95, 105, and 107, which are relative ratios to the reference error value of D4, at a position of L2 in which the reference error value of D4 is defined.

TABLE 8

| | L1 | L2 | L3 | L4 | L5 |
|---|---|---|---|---|---|
| D1 | 99 | 110 | 117.7 | 121 | 104.5 |
| D2 | 85.5 | 95 | 101.65 | 104.5 | 90.25 |
| D3 | 94.5 | 105 | 112.35 | 115.5 | 99.75 |
| D4 | 90 | 100 | 107 | 110 | 95 |
| D5 | 96.3 | 107 | 114.49 | 117.7 | 101.65 |

As described above, through the unit cycle, while the test target semiconductor devices are irradiated with the test beam, the error values for the test target semiconductor devices may be measured. One test target semiconductor device having a medium value or an error value adjacent to the medium value without having a maximum error value and a minimum error value among the test target semiconductor devices may be defined as a reference test target semiconductor device, so that an error value of the reference test target semiconductor device may be defined as a reference error value, and a reference error value of a test target semiconductor device (a general test target semiconductor device) other than the reference test target semiconductor device may be defined as a relative ratio to the reference error value of the reference test target semiconductor device. In addition, as described above, the reference test target semiconductor device may be defined as the one test target semiconductor device having the medium value or the error value adjacent to the medium value among the test target semiconductor devices, so that the general test target semiconductor device may include: a first type general test target semiconductor device having a reference error value that is higher than the reference error value of the reference test target semiconductor device; and a second type general test target semiconductor device having a reference error value that is lower than the reference error value of the reference test target semiconductor device.

In other words, through the unit cycle, D1 to D5 may be irradiated with the test beam of the same dose, and reference error values of the test target semiconductor devices may be defined, respectively, based on the error values measured while the irradiation of the test beam of the same dose is performed. Accordingly, a fluctuation of an error value according to a difference in dose for each region of the test beam subjected to the irradiation may be minimized, so that reliability of the reference error values of the test target semiconductor devices may be ensured.

According to one embodiment, unlike the configuration described above, other statistical methods may also be used. In detail, a reference dose value may also be set while setting the reference error value. In this case, there may be a case where both the reference error value and the reference dose value are unknown, a case where one of the reference error value and the reference dose value is known, and a case where both the reference error value and the reference dose value are known. In this case, a third reference error value and a third reference dose value may be calculated. For example, when an average dose value of the beam and an error range according to a variation in dose are given as shown in the examples of FIGS. 4 and 5, a medium value of the test target semiconductor device may be calculated as in the examples of FIGS. 10 to 15. In this case, as shown in the examples of FIGS. 10 to 15, the medium value has changed proportionally at other positions in which the variation in dose has occurred. A proportional deviation of the average dose value has been distributed to exhibit a proportional deviation of the error value based on the medium value of the test target semiconductor device. It is also obvious fact that a dose value of the test beam may be obtained through the same proportional relation by using the medium value of the test target semiconductor device.

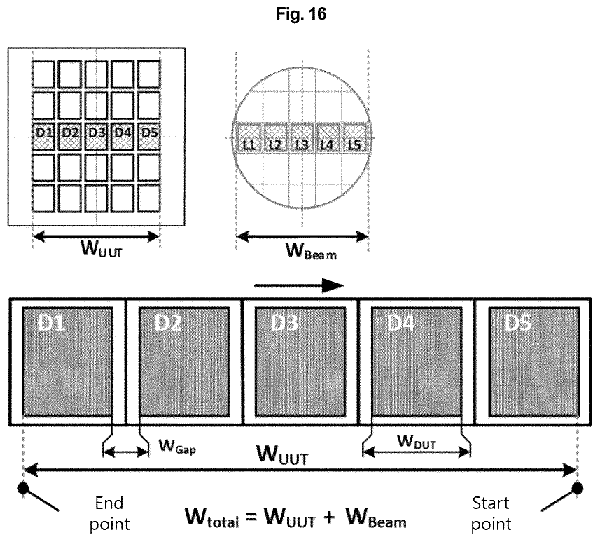

During the unit cycle, depending on a measurement scheme, the beam irradiation region and the test target semiconductor devices may overlap each other in a stepwise manner, or the beam irradiation region may perform movement/scanning at a constant speed (continuously) on the test target semiconductor devices. Hereinafter, a stepwise overlapping process and a scanning process will be described with reference to FIGS. 16 to 19.

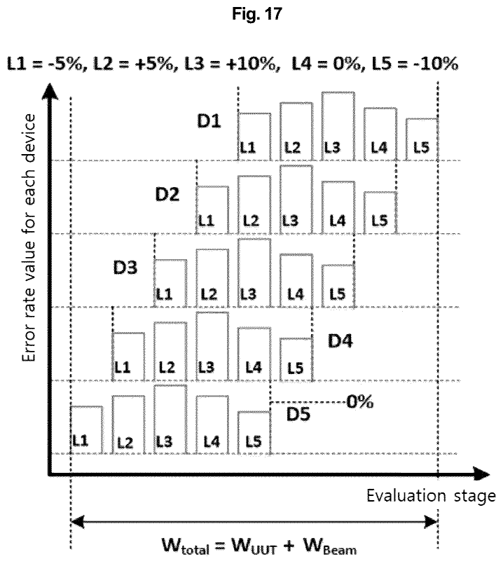

FIG. 16 is a view for describing a stepwise overlapping process and a scanning process in the method for evaluating the semiconductor device and the system for evaluating the semiconductor device according to the embodiment of the present disclosure, and FIG. 17 is a graph showing an error value for each device according to stepwise overlapping in the method for evaluating the semiconductor device and the system for evaluating the semiconductor device according to the embodiment of the present disclosure.

Referring to FIGS. 11, 16, and 17, as described with reference to FIG. 11, the test target semiconductor devices D1 to D5 may be provided, and the beam irradiation region having L1 to L5 may be provided.

The test board 110 may move every time after a reference time has elapsed. That is, the test board 110 may move in a stepwise or step-like arrangement on a chip basis, a cell basis, or a predetermined grid basis. In other words, while L1 overlaps D5, the test board 110 may move after the reference time has elapsed. Due to the movement of the test board 110, L1 and L2 may overlap D4 and D5, respectively, and the test board 110 may move after the reference time has elapsed. Due to the movement of the test board 110, L1, L2, and L3 may overlap D3, D4, and D5, respectively, and the test board 110 may move after the reference time has elapsed. Due to the movement of the test board 110, L1, L2, L3, and L4 may overlap D2, D3, D4, and D5, respectively, and the test board 110 may move after the reference time has elapsed. Due to the movement of the test board 110, L1, L2, L3, L4, and L5 may overlap D1, D2, D3, D4, and D5, respectively, and the test board 110 may move after the reference time has elapsed. Due to the movement of the test board 110, L2, L3, L4, and L5 may overlap D1, D2, D3, and D4, respectively, and the test board 110 may move after the reference time has elapsed. Due to the movement of the test board 110, L3, L4, and L5 may overlap D1, D2, and D3, respectively, and the test board 110 may move after the reference time has elapsed. Due to the movement of the test board 110, L4 and L5 may overlap D1 and D2, respectively, and the test board 110 may move after the reference time has elapsed. Due to the movement of the test board 110, L5 may overlap D1, and the test board 110 may move after the reference time has elapsed. Accordingly, the unit cycle may be terminated.

As shown in FIG. 16, when a width of the test target semiconductor device is defined as W_{DUT}, and a gap between the test target semiconductor devices is defined as W_{Gap}, a total width W_{UUT} may be defined as a sum of W_{DUT} and W_{Gap}.

In addition, when a width of the test beam is defined as W_{Beam}, a total width Wₜₒₜₐₗ at which the test target semiconductor device is irradiated with the test beam may be defined as a sum of W_{UUT} and W_{Beam}.

In addition, when the unit cycle based on stepwise overlapping is performed after the reference time has elapsed, an error rate value for each of positions L1 to L5 of the test target semiconductor devices D1 to D5 may be displayed as shown in FIG. 17. The graph of FIG. 17 has been created with reference to the data in Table 1 and the graph of FIG. 12.

In addition, it is obvious to those skilled in the art that the test beam may have various shapes, such as a quadrangular shape and an elliptical shape, other than a circular shape.

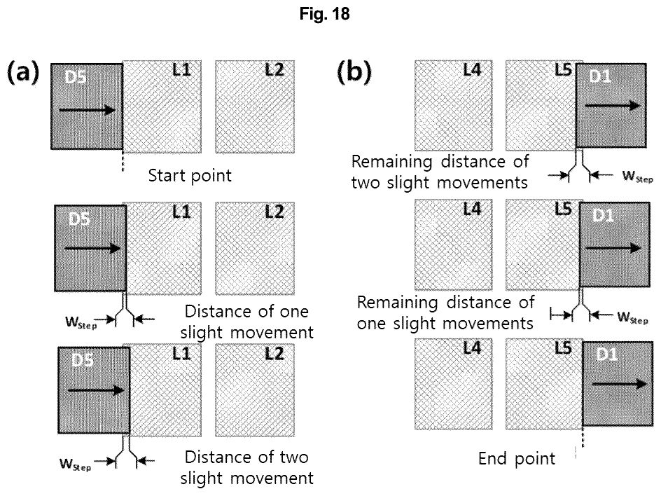

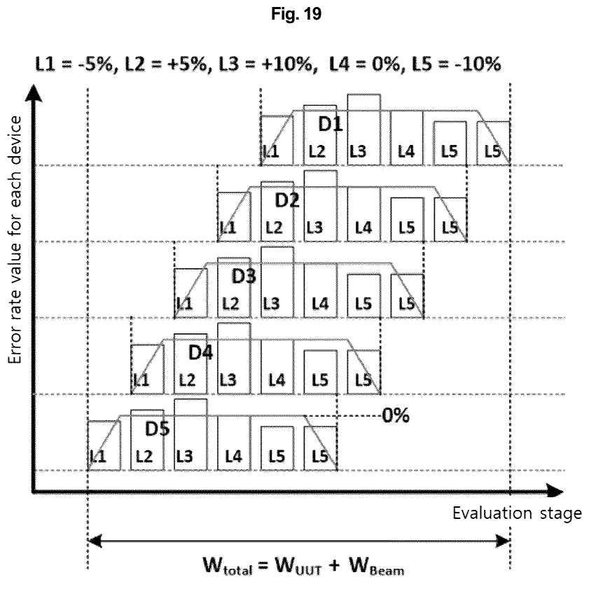

FIG. 18 is a view for describing the scanning process in the method for evaluating the semiconductor device and the system for evaluating the semiconductor device according to the embodiment of the present disclosure, and FIG. 19 is a graph showing an error value for each device according to the scanning process in the method for evaluating the semiconductor device and the system for evaluating the semiconductor device according to the embodiment of the present disclosure.

Referring to FIGS. 11, 18, and 19, as described with reference to FIG. 11, the test target semiconductor devices D1 to D5 may be provided, and the beam irradiation region having L1 to L5 may be provided.

The test board 110 may move (continuously) at a constant speed. In other words, the test board 110 may move at a constant speed, so that D1 to D5 may overlap L1 to L5. In detail, as shown in FIG. 18, when the L1 starts to be located on D5, a movement may be performed at a constant speed, so that L1 may be located on D5, D4, D3, D2, and D1, L2 may be located on D5, D4, D3, D2, and D1 from a time point at which L1 is not located on D5 (overlapping is terminated), L3 may be located sequentially on D5, D4, D3, D2, and D1 from a time point at which L2 is not located on D5 (overlapping is terminated), L4 may be located sequentially on D5, D4, D3, D2, and D1 from a time point at which L3 is not located on D5 (overlapping is terminated), and L5 may be located sequentially on D5, D4, D3, D2, and D1 from a time point at which L4 is not located on D5 (overlapping is terminated).

When the unit cycle is performed by the scanning process as described above, an error rate value for each of the positions L1 to L5 of the test target semiconductor devices D1 to D5 may be displayed as shown in FIG. 19. The graph of FIG. 19 has been created with reference to the data in the graph of FIG. 12. In addition, a dose of the test beam with which the test target semiconductor device is irradiated may be calculated as an integral value.

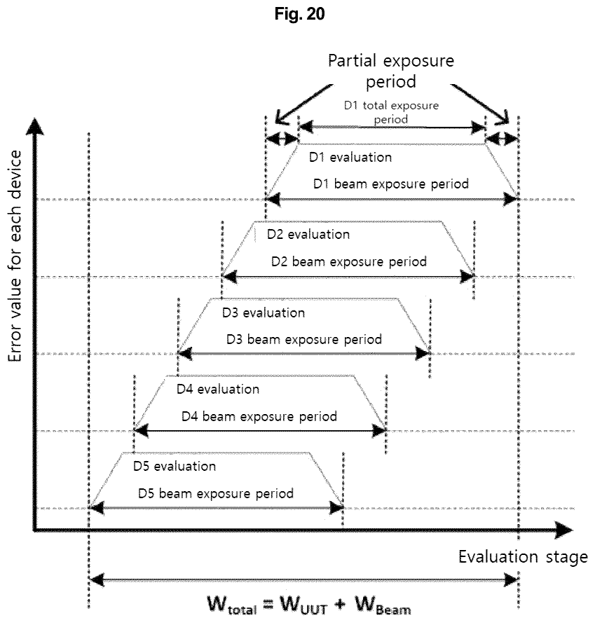

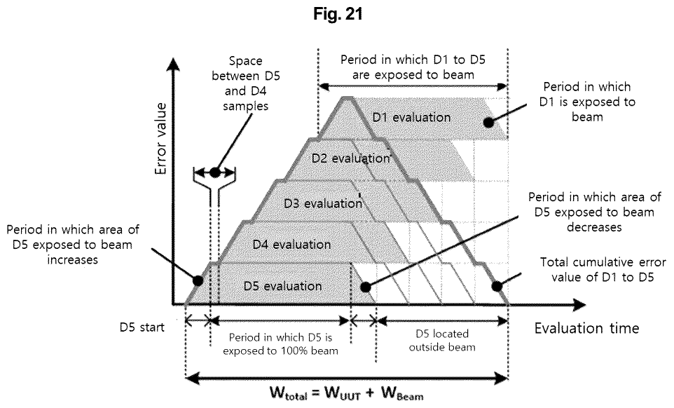

FIGS. 20 and 21 are graphs for describing sameness of a dose of the test beam with which the test target semiconductor device is irradiated in the method for evaluating the semiconductor device and the system for evaluating the semiconductor device according to the embodiment of the present disclosure.

Referring to FIGS. 20 and 21, as described with reference to FIG. 11, the test target semiconductor devices D1 to D5 may be provided, the beam irradiation region having L1 to L5 may be provided, and D1 to D5 may be irradiated with the test beam.

As shown in FIGS. 20 and 21, periods during which D1 to D5 are exposed to the test beam may be the same as each other. In other words, since times for which D1 to D5 are exposed to the test beam are the same as each other, and all of D1 to D5 overlap L1 to L5, even when there is a difference in dose among L1 and L5, which are the beam irradiation region of the test beam, doses of the test beam with which D1 to D5 located on the same X axis are irradiated may be substantially the same as each other. In other words, due to a result of the stepwise overlapping process or the scanning process described above, the test target semiconductor device arranged in a direction parallel to the direction in which the test beam is moved may be irradiated with the test beam of substantially the same dose for substantially the same time (for the same movement time), so that accumulated doses may be substantially the same as each other.

In conclusion, in a process of the unit cycle in which the test target semiconductor devices D1 to D5 are irradiated while the beam irradiation region L1 to L5 irradiated with the test beam is moved, the doses of the test beam with which the test target semiconductor devices are irradiated may be substantially the same as each other, so that a difference in error value according to a difference in dose for each region of the test beam may be minimized, and thus reliability of the reference error values of the test target semiconductor devices may be improved.

In other words, according to FIGS. 20 and 21 and the descriptions referring thereto, reference errors of D1 to D5 may be calculated, and reference doses of L1 to L5 may also be calculated. When one value of the reference error or the reference dose is known, an unknown value of the reference error or the reference dose may be derived. In addition, as shown in FIG. 21, the reference dose value may configure a profile of a continuous beam. In addition, an average error value of each device may be obtained from cumulative evaluation values of D1 to D5.

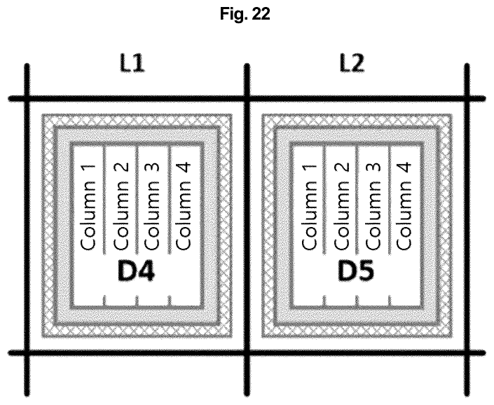

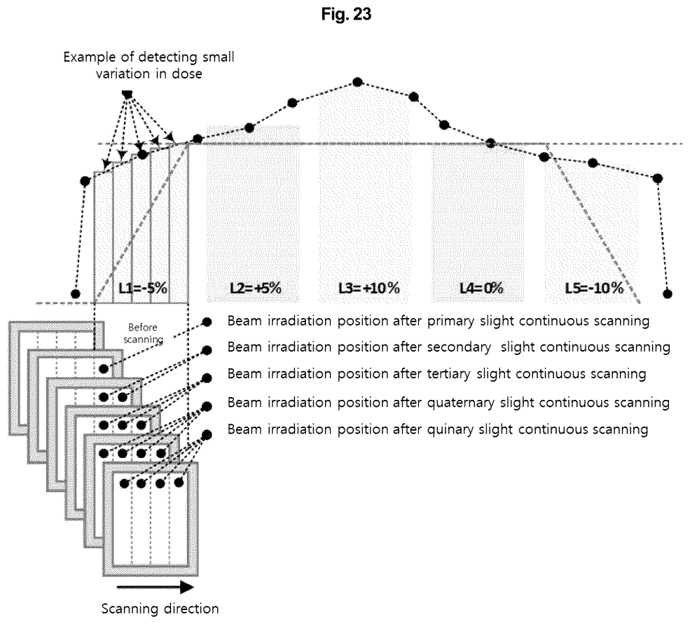

FIG. 22 is a view for describing an internal structure of the test target semiconductor device according to the embodiment of the present disclosure, and FIG. 23 is a view for describing a process of applying the method for evaluating the semiconductor device according to the embodiment of the present disclosure to the test target semiconductor device having the internal structure of FIG. 22.

Referring to FIGS. 22 and 23, the test target semiconductor devices D4 and D5 described with reference to FIG. 11 may be provided to overlap the beam irradiation region L1 and L2, respectively.

As shown in FIGS. 22, D4 and D5 may include a plurality of columns. In this case, as shown in FIG. 23, when D5 starts to overlap L1, Column 4 may overlap L1, which is the beam irradiation region of the test beam, Column 4 and Column 3 may subsequently overlap L1, Column 4, Column 3, and Column 2 may subsequently overlap L1, Column 4, Column 3, Column 2, and Column 1 may subsequently overlap L1, Column 3, Column 2, and Column 1 may subsequently overlap L1, Column 2 and Column 1 may subsequently overlap L1, and Column 1 may overlap L1, so that an error value when D5 overlaps L1 may be measured.

In other words, the test board 110 may be moved to correspond to an interval of the columns of the test target semiconductor device D5, so that the columns within the test target semiconductor device D5 may be irradiated with the test beam of substantially the same dose. In other words, the test board 110 may be moved such that one column (Column 4) within the test target semiconductor device may be located to overlap the beam irradiation region of the test beam, and, after the reference time has elapsed, the test board 110 may be moved such that so that Column 4 and Column 3 within the test target semiconductor device may be located to overlap the beam irradiation region of the test beam, so that the test board 110 may be moved.

Thereafter, an error value while D5 overlaps L1 may be measured as a sum of error values that occur in the columns, respectively.

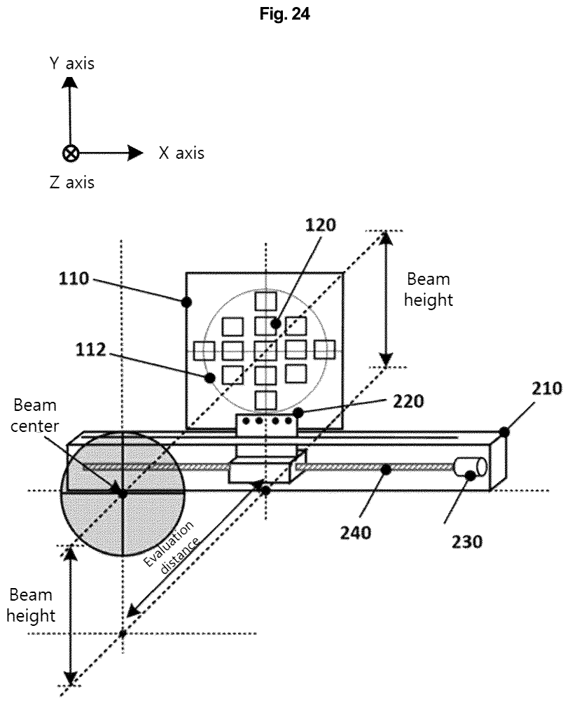

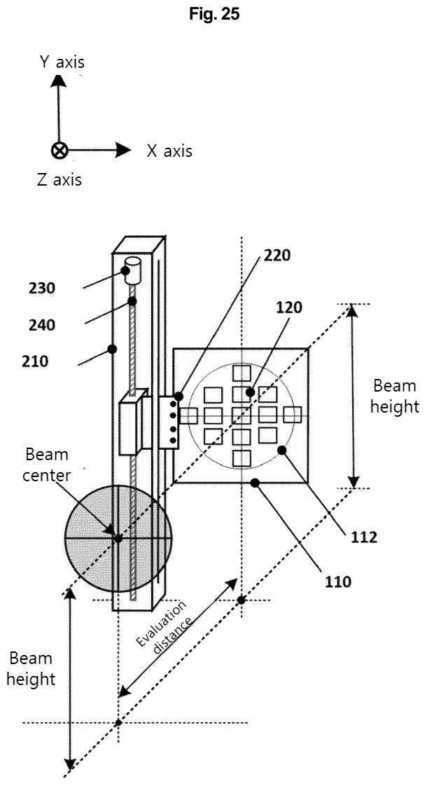

In addition, a system for evaluating a semiconductor device shown in FIGS. 24 and 25, which will be described below, may be used to perform the irradiation of the test beam more easily and precisely according to a column position of a memory device described with reference to FIGS. 22 and 23, and analyze a profile of the test beam in more detail through analysis of an error rate according to a column. In other words, an evaluation and analysis technology applied to the test target semiconductor device may be applied to a fine column structure, so that dose analysis and evaluation for the test beam may be performed more finely and precisely.

FIGS. 24 and 25 are views for describing the system for evaluating the semiconductor device according to the embodiment of the present disclosure.

Referring to FIGS. 24 and 25, according to the embodiment of the present disclosure, the system for evaluating the semiconductor device may include: a gripping part 220 configured to fix the test board 110; a driving motor 230 and a driving gear 240, which are configured to move the gripping part 220; and a control unit 210 configured to control the driving motor 230.

The system for evaluating the semiconductor device of FIG. 24 may move the test board 110 in the X axis direction, and the system for evaluating the semiconductor device of FIG. 25 may move the test board 110 in the Y axis direction.

Accordingly, the test board 110 may be easily moved while being stably fixed, so that the method for evaluating the semiconductor device according to the embodiment of the present disclosure described with reference to FIGS. 1 to 23 may be easily performed.

However, in addition to the method shown in FIGS. 24 and 25, the test board 110 may be moved through various methods and various configurations, and the technical idea according to the embodiment of the present disclosure is not limited to the configurations of the systems for evaluating the semiconductor devices shown in FIGS. 24 and 25. In other words, one driving apparatus obtained by integrating the configurations of FIGS. 24 and 25 with each other may be implemented, and an apparatus capable of moving along the Z axis may be further implemented.

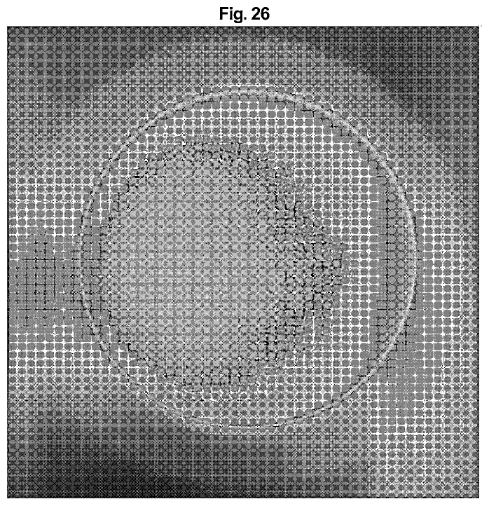

A method for evaluating a radiation of a semiconductor device, a system for evaluating a radiation of a semiconductor device, a method for evaluating a beam characteristic, and a system for evaluating a beam characteristic, by using a reference semiconductor device, according to an embodiment of the present disclosure will be described with reference to FIGS. 26 to 46.

FIG. 26 is a view for describing the difference in dose for each region of the test beam used in the system for evaluating the semiconductor device according to the embodiment of the present disclosure.

Referring to FIG. 26, a differences in dose may occur for each region in a beam irradiation region irradiated with a test beam. In other words, as shown in FIG. 26, a relatively dark region (a gray or black region in FIG. 26) may be a region irradiated with a relatively small dose of the test beam, and a relatively pale region (a region that strongly exhibits white in FIG. 26) may be region irradiated with a relatively high dose of the test beam.

In other words, a beam profile of the test beam may not be uniform within the beam irradiation region, so that there may be a limitation in accurate measurement of error values and error ratios of a plurality of test target semiconductor devices by the test beam.

Therefore, in order to accurately measure the error values and the error ratios of the test target semiconductor devices, accurate measurement of uniformity (dose uniformity and a dose value) of the beam profile of the test beam may be required.

However, in a case of a general test target semiconductor device, a sensitivity to the test beam subjected to the irradiation may vary for each test target semiconductor device, so that there may be a limitation in measuring a dose value (uniformity of the beam profile) for each region of the test beam by using the general test target semiconductor device.

However, according to the embodiment of the present disclosure, the dose value (the uniformity of the beam profile) for each region of the test beam may be easily and accurately measured by using a reference semiconductor device having a reference error value.

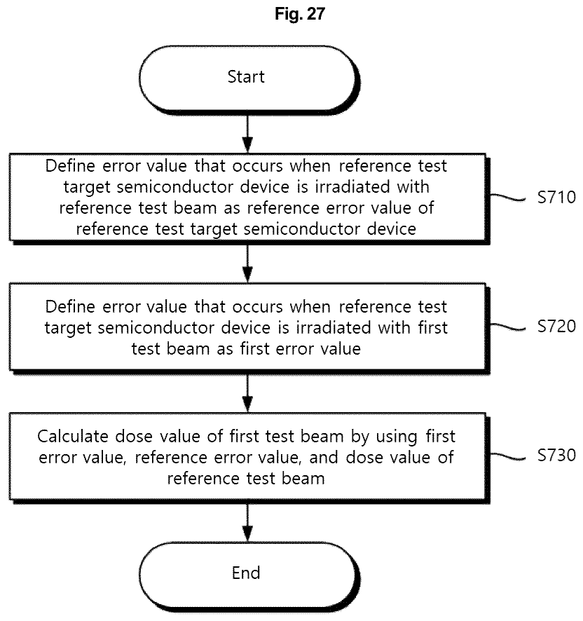

Hereinafter, a method for evaluating a beam characteristic and a system for evaluating a beam characteristic, by using a reference semiconductor device, according to an embodiment of the present disclosure will be described with reference to FIGS. 27 to 29.

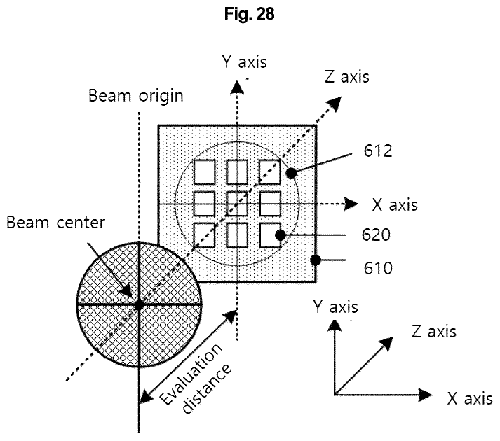

FIG. 27 is a flowchart for describing a method for evaluating a beam characteristic by using a reference semiconductor device according to an embodiment of the present disclosure, and FIG. 28 is a view for describing the method for evaluating the beam characteristic by using the reference semiconductor device and a method for evaluating a reference error value of a reference semiconductor device according to the embodiment of the present disclosure.

Referring to FIGS. 27 and 28, an error value that occurs when a reference test target semiconductor device is irradiated with a reference test beam may be defined as a reference error value of the reference test target semiconductor device (S710).

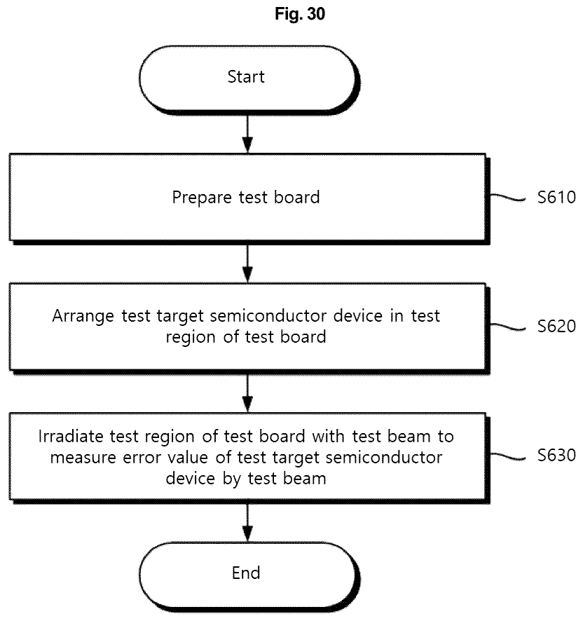

The reference test target semiconductor device may be a test target semiconductor device having the reference error value or capable of determining the reference error value, and a specific method for irradiating the reference test target semiconductor device with the reference test beam and a specific method for defining the reference error value of the reference test target semiconductor device will be described below with reference to FIGS. 30 to 33.

A test board 610 may be prepared, and a plurality of test target semiconductor devices 620 may be arranged in the test region 612 of the test board. According to one embodiment, some of the test target semiconductor devices 620 may be the reference test target semiconductor device. Alternatively, according to another embodiment, all of the test target semiconductor devices 620 may be the reference test target semiconductor devices. For convenience of description, the description will be made on the assumption that a plurality of reference test target semiconductor devices 620 are arranged on the test board 610, but it is obvious that embodiments are not limited thereto.

The reference test target semiconductor devices 620 may be irradiated with a first test beam, and an error value that occurs when the reference test target semiconductor devices 620 are irradiated with the first test beam may be defined as a first error value (S720).

In other words, the test board 610 on which the reference test target semiconductor device 620 is arranged may be irradiated with the first test beam, an error may occur in the reference test target semiconductor device 620 by the first test beam, and the number of occurrences of errors may be counted as the first error value.

A dose value of the first test beam may be calculated by using the first error value, the reference error value of the reference test target semiconductor device 620, and a dose value of the reference test beam (S730). The dose value may be a beam profile, in which a degree of variation according to a position from an average dose value may be displayed in a unit of %.

In detail, the dose value of the first test beam may be calculated by using <Formula 1> below.

In <Formula 1> below, B1 is a dose value of a first test beam, E1 is a first error value, BS is a dose value of a reference test beam, and ES is a reference error value.

$$B 1 = ( E 1 \times BS ) / ES \qquad < Formula 1 >$$

As shown in <Formula 1>, the dose value of the first test beam may be calculated as a value obtained by multiplying an error value E1 measured by the first test beam in the reference test target semiconductor device 620 by the dose value BS of the reference test beam, and dividing a multiplication result by the reference error value ES that occurs by the reference test beam in the reference test target semiconductor device 620.

As shown in FIG. 28, when the reference test target semiconductor devices 620 are arranged in the test board 610, the dose value of the first test beam may be calculated by using the method described above for each of regions in which the reference test target semiconductor devices 620 are arranged. In other words, as shown in FIG. 28, when nine reference test target semiconductor devices 620 are arranged, dose values of the first test beam for nine regions may be calculated for each of the regions in which the reference test target semiconductor devices 620 are arranged, and the dose values of the first test beam for the nine regions may be summed up to calculate the dose value (beam profile uniformity) for each region of the first test beam.

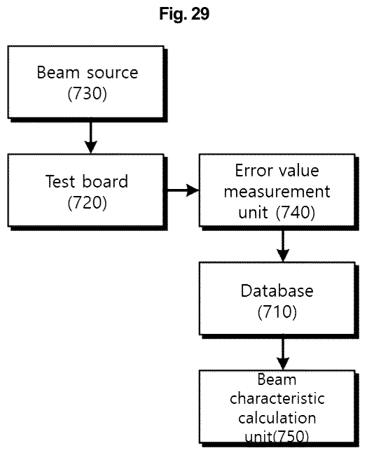

FIG. 29 is a block diagram for describing a system for evaluating a beam characteristic by using a reference semiconductor device according to an embodiment of the present disclosure.

Referring to FIG. 29, according to an embodiment of the present disclosure, a system for evaluating a beam characteristic may include a database 710, a test board 720, a beam source 730, an error value measurement unit 740, and a beam characteristic calculation unit 750.

As described with reference to FIGS. 27 and 28, the database 710 may receive a reference error value that occurs when the reference test target semiconductor device is irradiated with the reference test beam from the error value measurement unit 740 to store the received reference error value, and may store a dose value of the reference test beam.

As described with reference to FIGS. 27 and 28, the reference test target semiconductor devices may be arranged on the test board 720.

As described with reference to FIGS. 27 and 28, the beam source 730 may irradiate the reference test target semiconductor device on the test board 720 with the first test beam.

As described with reference to FIGS. 27 and 28, the error value measurement unit 740 may measure the first error value that occurs in the reference test target semiconductor device by the first test beam.

As described with reference to FIGS. 27 and 28, the beam characteristic calculation unit 750 may receive the reference error value and the dose value of the reference test beam, which are stored in the database 710, and the first error value, and may calculate a dose value of the first test beam by using the received values.

Hereinafter, a method for calculating a reference error value of a reference test target semiconductor device will be described with reference to FIGS. 30 to 33.

FIG. 30 is a flowchart for describing a method for calculating a reference error value of a reference test target semiconductor device in the method for evaluating the semiconductor device according to the embodiment of the present disclosure.

Referring to FIG. 30, a test board may be prepared (S610), a plurality of reference test target semiconductor devices may be arranged in a test region of the test board (S620), and the test region of the test board may be irradiated with a reference test beam to measure error values of the reference test target semiconductor devices by the reference test beam (S630).

In this case, a beam irradiation region within the test region, which is irradiated with the reference test beam, may be changed. In other words, the beam irradiation region within the test region may be moved, expanded, and/or contracted, so that the reference test target semiconductor devices may be irradiated with the reference test beam at the same dose, and, as a result, reference error values and error ratios of the reference test target semiconductor devices may be determined.

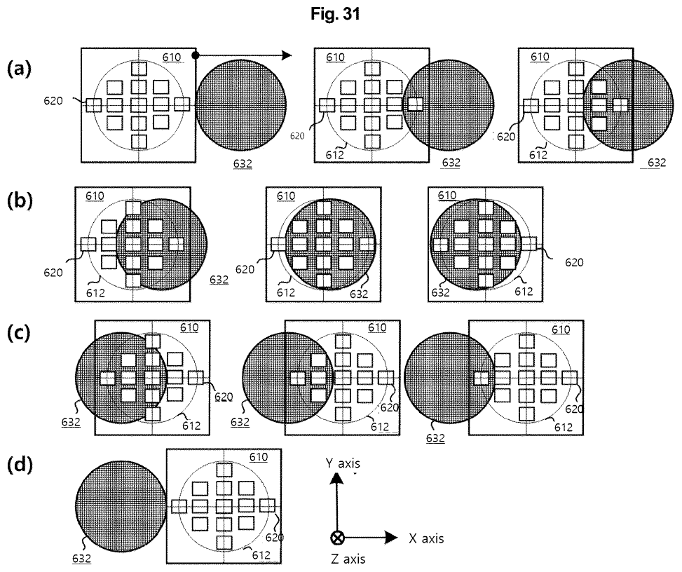

FIG. 31 is a view for describing a process of moving the beam irradiation region in the method for calculating the reference error value of the test target semiconductor device in the method for evaluating the semiconductor device according to the embodiment of the present disclosure.

Referring to FIG. 31, the reference test target semiconductor devices 620 may be arranged on the test board 610, and a beam irradiation region 632 irradiated with the reference test beam may be provided.

Although the test board 610 has been described with reference to FIG. 31 as being moved in the direction parallel to the X axis of FIG. 31, embodiments are not limited thereto, and it is obvious to those skilled in the art that the test board 610 may be moved in the direction parallel to the Y axis of FIG. 31, or the test board 610 may be moved in the direction parallel to the Z axis of FIG. 31. In addition, although the test board 610 has been described as being moved, embodiments are not limited thereto, and it is obvious that the test board 610 may be fixed, and the beam source configured to perform the irradiation of the reference test beam may be moved. In addition, the test board 610 and the beam source may be moved simultaneously.

In addition, in the description with reference to FIG. 31, it is obvious to those skilled in the art that the reference test target semiconductor devices 620 may be arranged in a form and an arrangement that are different from the form and the arrangement of the reference test target semiconductor devices 620 arranged on the test board 610.

In addition, although the reference test target semiconductor devices 620 have been described with reference to FIG. 31 as being arranged on the test board 610, embodiments are not limited thereto, and it is obvious to those skilled in the art that one reference test target semiconductor device 620 may be arranged on the test board 610.

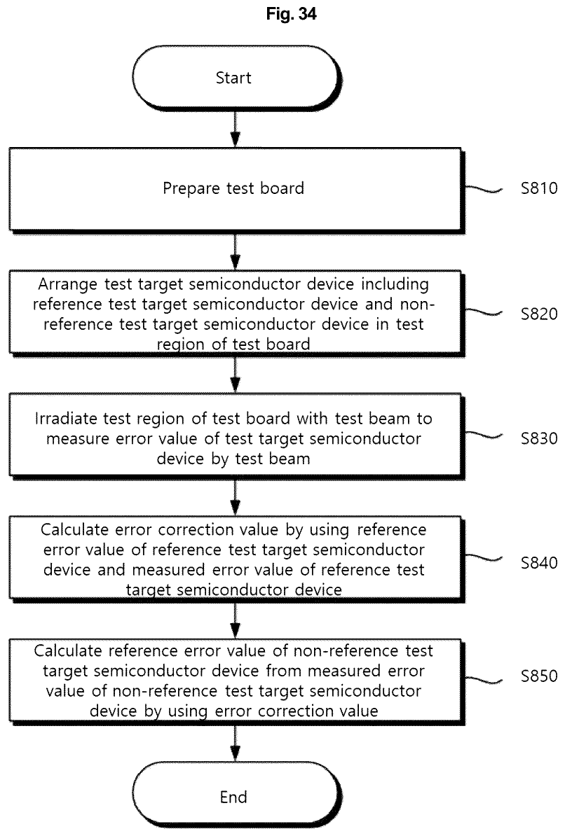

Next, referring to FIG. 31, as shown in (a) to (d) of FIG. 34, the beam irradiation region 632 may be located outside the test board 610, and as the beam irradiation region 632 gradually moves, the rightmost reference test target semiconductor device 620 and the beam irradiation region 632 may overlap each other so that the rightmost reference test target semiconductor device 620 may be irradiated with the reference test beam, and sequentially, the reference test target semiconductor devices 620 located on a left side of the rightmost reference test target semiconductor device 620 may also be irradiated with the reference test beam. Finally, the leftmost reference test target semiconductor device 620 and the beam irradiation region 632 may overlap each other so that the leftmost reference test target semiconductor device 620 may be irradiated with the reference test beam, and the irradiation for the reference test target semiconductor devices 620 with of the reference test beam may be terminated.

As described above, while the test target semiconductor devices 620 are irradiated with the reference test beam, that is, while the beam irradiation region 632 overlaps the test target semiconductor devices 620, errors that occur in the test target semiconductor devices 620 may be measured and counted. The errors that occur in the test target semiconductor devices 620 may be measured, counted, and analyzed.

According to one modified example, as described with reference to FIG. 31, after the irradiation of the reference test beam is performed from the rightmost reference test target semiconductor device 620 to the leftmost reference test target semiconductor device 620, the irradiation of the reference test beam may be performed again from the leftmost reference test target semiconductor device 620 to the rightmost reference test target semiconductor device 620.

As described above, when a process of irradiating all of the reference test target semiconductor devices 620 with the reference test beam is defined as a unit cycle, the unit cycle may be performed once or a plurality of times, and the errors that occur in the reference test target semiconductor devices 620 may be measured and counted while the unit cycle is performed once or a plurality times.

In addition, as in one modified example described above, when the unit cycle is performed a plurality of times, directions in which the reference test beam is moved may be the same as or different from each other. In other words, for example, when the unit cycle is performed twice, as described with reference to FIG. 31, after the reference test beam is moved from the rightmost reference test target semiconductor device 620 to the leftmost reference test target semiconductor device 620, the reference test beam may be moved from the leftmost reference test target semiconductor device 620 to the rightmost reference test target semiconductor device 620. That is, the test board 610 may be moved in a +direction (a movement from left to right) and a −direction (a movement from right to left) along the X axis, so that the unit cycle may be performed.

Alternatively, for another example, when the unit cycle is performed twice, in a first unit cycle, the test board 610 may be moved in the +direction or the −direction along the X axis, and, in a second unit cycle, the test board 610 may be moved in a +direction (a movement from bottom to top) or a −direction (a movement from top to bottom) along the Y axis.

Alternatively, for still another example, when the unit cycle is performed twice, in the first unit cycle, the test board 610 may be moved in the +direction or the −direction along the X axis, and, in the second unit cycle, the test board 610 may be moved in a +direction (a movement from paper to a viewer) or a −direction (a movement from the viewer to the paper) along the Z axis.

Alternatively, for yet another example, when the unit cycle is performed twice, in the first unit cycle, the test board 610 may be moved in the +direction or the −direction along the Y axis, and, in the second unit cycle, the test board 610 may be moved in the +direction or the −direction along the Z axis.

As described above, when the unit cycle is performed a plurality of times, directions in which the test board 610 is irradiated with the reference test beam may be the same as or different from each other in a plurality of unit cycles.

In addition, unlike the configuration in which the beam irradiation region 632 and/or the test board 610 moves on a grid basis after a reference time has elapsed as described with reference to FIG. 31, the beam irradiation region 632 and/or the test board 610 may move slightly at a constant speed. In other words, the technical idea according to the embodiment of the present disclosure is not limited to a movement scheme of the beam irradiation region 632 and/or the test board 610.

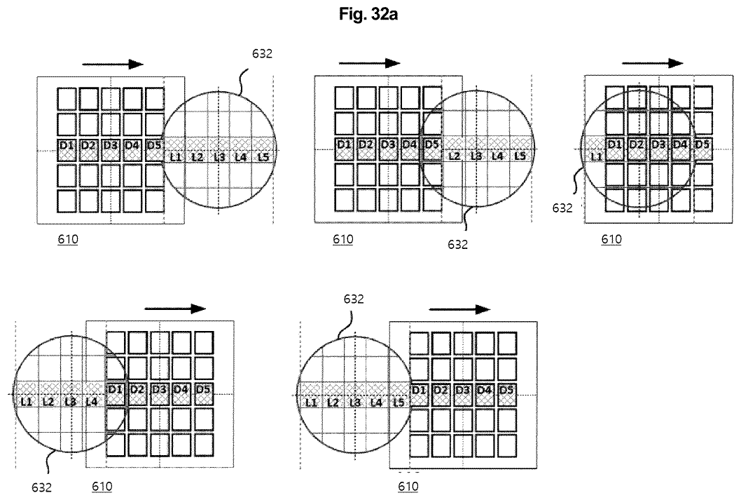

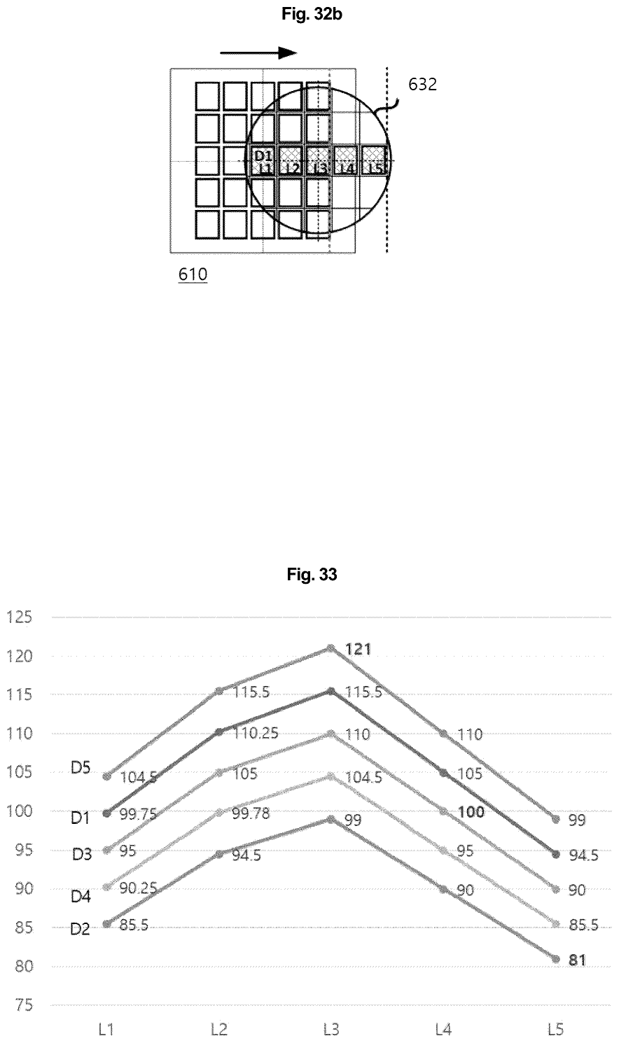

FIG. 32a is a view for describing the overlapping process of the beam irradiation region and the test region of FIG. 31, FIG. 32b is a view for describing evaluation of a dose by using one test target semiconductor device in the method for evaluating the semiconductor device according to the embodiment of the present disclosure, and FIG. 33 is a graph showing an error value of the reference test target semiconductor device measured according to the method for calculating the reference error value of the reference test target semiconductor device in the method for evaluating the semiconductor device according to the embodiment of the present disclosure.

Referring to FIG. 32a, the beam irradiation region irradiated with the reference test beam may be partitioned into a plurality of grids, and regions L1 to L5 may be defined in the beam irradiation region.

In addition, the test region of the test board may also be partitioned into a plurality of grids to correspond to the beam irradiation region, and a plurality of reference test target semiconductor devices D1 to D5 may be arranged in the test region.

Thereafter, as shown in FIG. 32, D5 may overlap L1, D4, D3, D2, and D1 may sequentially overlap L1, and finally, D1 may overlap L5, so that the unit cycle may be terminated.

As described above, during the unit cycle, error values of the reference test target semiconductor devices D1 to D5 for L1 to L5 may be measured and counted.

For example, when a difference in dose among L1 to L5 compared with an average value of a total dose is as shown in <Table 9> below, and a difference the reference error value of D1 to D5 is as shown in <Table 10> below, an error value may be measured as shown in <Table 11> below and FIG. 33.

As shown in <Table 11> below and FIG. 33, the measured error value had a maximum value of 621 when D5 is located at L3, and the measured error value had a minimum value of 81 when D2 is located at L5. Among the plurality of error values, when 100, which is a value adjacent to a medium value, is used as a reference, an error value of D3 located at L4 may be defined as a reference error value of D3, and reference error values of D1, D2, D4, and D5 may be defined as 105, 90, 95, and 610, which are relative ratios to the reference error value of D3, at a position of L4 in which the reference error value of D3 is defined.

TABLE 9

| L1 | L2 | L3 | L4 | L5 |
|---|---|---|---|---|
| −5% | +5% | +10% | 0% | −10% |

TABLE 10

| D1 | D2 | D3 | D4 | D5 |
|---|---|---|---|---|
| 105 | 90 | 100 | 95 | 610 |

TABLE 11

| | L1 | L2 | L3 | L4 | L5 |
|---|---|---|---|---|---|
| D1 | 99.75 | 610.25 | 115.5 | 105 | 94.5 |
| D2 | 85.5 | 94.5 | 99 | 90 | 81 |
| D3 | 95 | 105 | 610 | 100 | 90 |
| D4 | 90.25 | 99.78 | 104.5 | 95 | 85.5 |
| D5 | 104.5 | 115.5 | 621 | 610 | 99 |

The values described in <Table 11> may be values measured as described above, or predetermined values. The values in <Table 11> may be values that proportionally show how much reference error values of the test target semiconductor devices differ from each other according to the test target semiconductor devices. The values may be used to estimate and determine a difference in dose.

As described above, through the unit cycle, while the reference test target semiconductor devices are irradiated with the reference test beam, the error values for the reference test target semiconductor devices may be measured. An error value of one reference test target semiconductor device D3 having a medium value or an error value adjacent to the medium value without having a maximum error value and a minimum error value among the reference test target semiconductor devices may be defined as a reference error value, and a reference error value of a reference test target semiconductor device D1, D2, D4, and D5 other than the reference test target semiconductor device D3 may be defined as a relative ratio to the reference error value of the one reference test target semiconductor device D3.

In other words, through the unit cycle, D1 to D5 may be irradiated with the reference test beam of the same dose, and reference error values of the reference test target semiconductor devices may be defined, respectively, based on the error values measured while the irradiation of the reference test beam of the same dose is performed. Accordingly, a fluctuation of an error value according to a difference in dose for each region of the reference test beam subjected to the irradiation may be minimized, so that reliability of the reference error value of the reference test target semiconductor devices may be ensured.

In addition, as shown in FIG. 32b, when one test target semiconductor device D1 provided, and each of L1 to L5 overlaps the one test target semiconductor device D1, error values of the test target semiconductor device D1 for L1 to L5 may be measured, and dose difference values of L1 to L5 in the test beam may be calculated by using the error values of the test target semiconductor device D1 for L1 to L5.

Hereinafter, a method and a system for evaluating a semiconductor device by using a reference semiconductor device according to a first embodiment of the present disclosure will be described with reference to FIGS. 34 to 36.

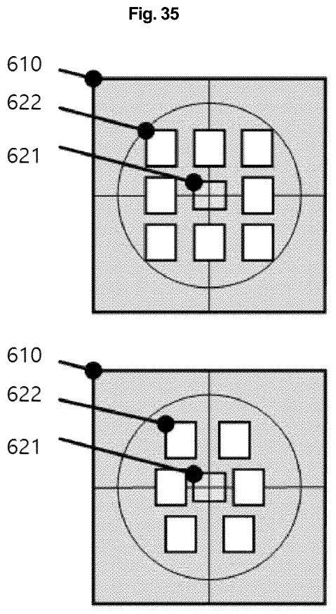

FIG. 34 is a flowchart for describing a method for evaluating a semiconductor device by using a reference semiconductor device according to a first embodiment of the present disclosure, and FIG. 35 is a view for describing the method for evaluating the semiconductor device by using the reference semiconductor device according to the first embodiment of the present disclosure.

Referring to FIGS. 34 and 35, a test board 610 may be prepared.

A plurality of test target semiconductor devices including a reference test target semiconductor device 621 and a non-reference test target semiconductor device 622 may be arranged in a test region of the test board 610 (S820).

The reference test target semiconductor device 621 may be a test target semiconductor device having a reference error value or capable of determining the reference error value. In other words, the reference test target semiconductor device 621 may be a test target semiconductor device in which a reference error value is defined by the method described with reference to FIGS. 30 to 33.

The non-reference test target semiconductor device 622 may be a test target semiconductor device in which a reference error value has not been determined.

According to one embodiment, as shown in FIG. 35, a plurality of non-reference test target semiconductor device 622 may be provided, the reference test target semiconductor device 621 may be arranged in a central region of the test region, and the non-reference test target semiconductor devices 622 may be arranged in an edge region of the test region, so that the non-reference test target semiconductor devices 622 may surround the reference test target semiconductor device 621.

Alternatively, according to another embodiment, unlike the configuration shown in FIG. 35, a plurality of reference test target semiconductor devices 621 and a plurality of non-reference test target semiconductor devices 622 may be provided, and the reference test target semiconductor devices 621 and the non-reference test target semiconductor devices 622 may be arbitrarily arranged.

The test region of the test board 610 may be irradiated with a test beam to measure error values of the test target semiconductor devices 621 and 622 by the test beam (S830).

When the test target semiconductor devices 621 and 622 arranged on the test board 610 are irradiated with the test beam, errors may occur in the test target semiconductor devices 621 and 622, and error values that occur in the test target semiconductor devices 621 and 622 may be measured and counted. In other words, each of the error value of the reference test target semiconductor device 621 and the error value of the non-reference test target semiconductor device 622, which occur by the test beam, may be measured and counted.

An error correction value may be calculated by using a reference error value of the reference test target semiconductor device 621 and the measured error value of the reference test target semiconductor device 621 (S840).

As described above, the reference error value of the reference test target semiconductor device 621 may be defined and determined. For example, the error correction value may be calculated by dividing the error value of the reference test target semiconductor device 621 that occurs by the test beam by the determined reference error value of the reference test target semiconductor device 621. In other words, the error correction value may be a value that compensates for a difference in error value that occurs in the reference test target semiconductor device 621 (a difference between the reference error value and the measured error value) according to a difference in dose between the test beam and the reference test beam. In other words, the error correction value may be a value that compensates for a difference in error value that occurs by the difference in dose between the test beam that is currently used and the reference test beam used to calculate the reference error value.

A reference error value of the non-reference test target semiconductor device 622 may be calculated from the measured error value of the non-reference test target semiconductor device 622 by using the error correction value (S850).

The reference error value of the non-reference test target semiconductor device 622 may be calculated by multiplying the error value of the non-reference test target semiconductor device 622 that occurs by the test beam by the error correction value. Accordingly, occurrence of a difference in error value according to a difference in dose of the test beam that is currently used may be compensated for, so that reliability of the error value of the non-reference test target semiconductor device 622 may be ensured.

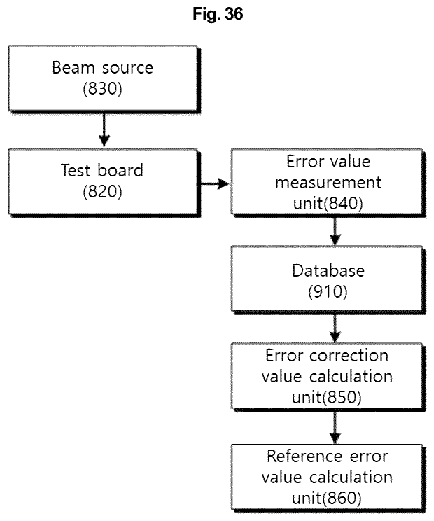

FIG. 36 is a block diagram for describing a system for evaluating a semiconductor device by using a reference semiconductor device according to a first embodiment of the present disclosure.

Referring to FIG. 36, according to an embodiment of the present disclosure, a system for evaluating a semiconductor device by using a reference semiconductor device may include a database 810, a test board 820, a beam source 830, an error value measurement unit 840, an error correction value calculation unit 850, and a reference error value calculation unit 860.

As described with reference to FIGS. 34 and 35, the database 810 may store a reference error value of the reference test target semiconductor device.

As described with reference to FIGS. 34 and 35, a plurality of test target semiconductor devices including a plurality of reference test target semiconductor devices and a plurality of non-reference test target semiconductor devices may be arranged in a test region of the test board 820.

As described with reference to FIGS. 34 and 35, the beam source 830 may irradiate the test region of the test board 820 with a test beam.

As described with reference to FIGS. 34 and 35, the error value measurement unit 840 may receive data from the test board 820, and may measure error values of the test target semiconductor devices including the reference test target semiconductor device and the non-reference test target semiconductor device by the test beam.

As described with reference to FIGS. 34 and 35, the error correction value calculation unit 850 may receive the reference error value of the reference test target semiconductor device, which is stored in the database 810, and the error value of the reference test target semiconductor device, which is measured by the error value measurement unit 840, and may calculate an error correction value by using the received values.

As described with reference to FIGS. 34 and 35, the reference error value calculation unit 860 may receive data from the error correction value calculation unit 850, and may calculate a reference error value of the non-reference test target semiconductor device from the error value of the non-reference test target semiconductor device, which is measured by the error value measurement unit 840, by using the error correction value.

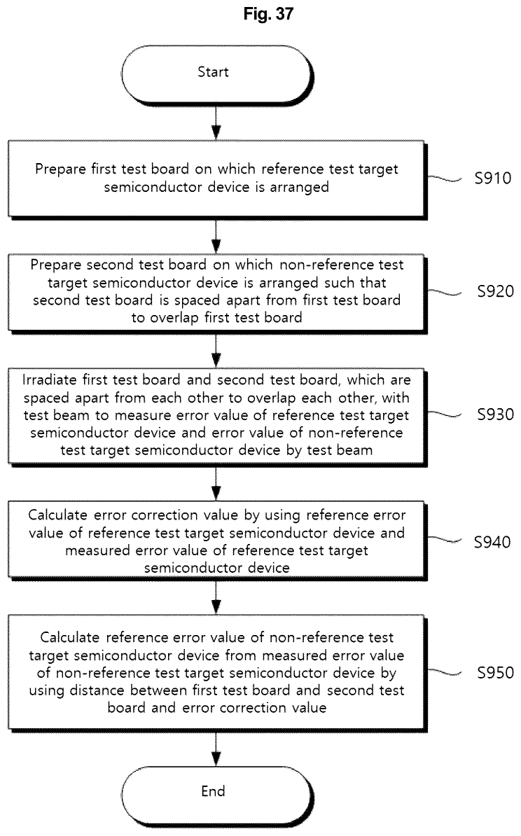

Hereinafter, a method and a system for evaluating a semiconductor device by using a reference semiconductor device according to a second embodiment of the present disclosure will be described with reference to FIGS. 37 to 40.

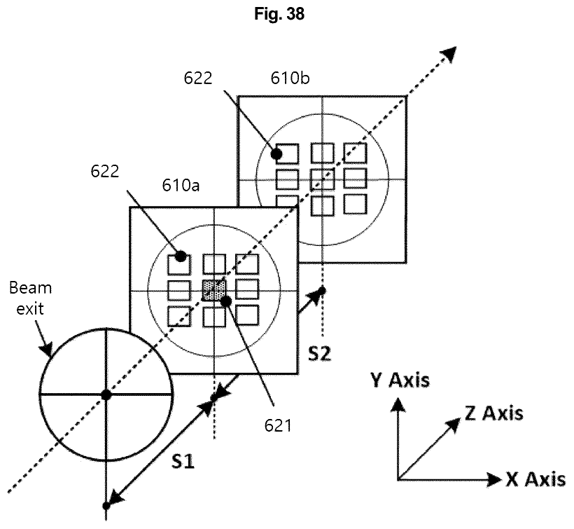

FIG. 37 is a flowchart for describing a method for evaluating a semiconductor device by using a reference semiconductor device according to a second embodiment of the present disclosure, and FIGS. 38 to 41 are views for describing the method for evaluating the semiconductor device by using the reference semiconductor device according to the second embodiment of the present disclosure.

Referring to FIGS. 37 and 38, a first test board 610a on which a reference test target semiconductor device 621 is arranged may be prepared (S910).

A plurality of non-reference test target semiconductor devices 622 may be arranged on the first test board 610a together with the reference test target semiconductor device 621. Alternatively, unlike the configuration shown in FIG. 38, a plurality of reference test target semiconductor devices 621 and a plurality of non-reference test target semiconductor devices 622 may be arranged on the first test board 610a. In other words, at least one reference test target semiconductor device 621 may be arranged on the first test board 610a.

As described above, the reference test target semiconductor device 621 may be a test target semiconductor device having a reference error value or capable of determining the reference error value. In other words, the reference test target semiconductor device 621 may be a test target semiconductor device in which a reference error value is defined by the method described with reference to FIGS. 5 to 33. In addition, the non-reference test target semiconductor device 622 may be a test target semiconductor device in which a reference error value has not been determined.

A second test board 610b on which the non-reference test target semiconductor device 622 is arranged may be prepared such that the second test board 610b may be spaced apart from the first test board 610a to overlap the first test board 610a (S920).

A plurality of non-reference test target semiconductor devices 622 may be arranged on the second test board 610b, and, as described above, the second test board 610b may be spaced apart from the first test board 610a to overlap the first test board 610a.

In addition, according to one embodiment, only the non-reference test target semiconductor device 622 may be arranged on the second test board 610b, and the reference test target semiconductor device 621 may not be arranged on the second test board 610b.

The first test board 610a and the second test board 610b, which are spaced apart from each other to overlap each other, may be irradiated with a test beam to measure an error value of the reference test target semiconductor device 621 and an error value of the non-reference test target semiconductor device 621 by the test beam (S930).

When the test target semiconductor devices 621 and 622 arranged on the test boards 610a and 610b are irradiated with the test beam, errors may occur in the test target semiconductor devices 621 and 622, and error values that occur in the test target semiconductor devices 621 and 622 may be measured and counted. In other words, each of the error value of the reference test target semiconductor device 621 and the error value of the non-reference test target semiconductor device 622, which occur by the test beam, may be measured and counted.

As shown in FIG. 38, the first test board 610a having at least one reference test target semiconductor device 621 may be first irradiated with the test beam, and subsequently, the second test board 610b having the non-reference test target semiconductor device 622 may be irradiated with the test beam that has been transmitted through the first test board 610a.

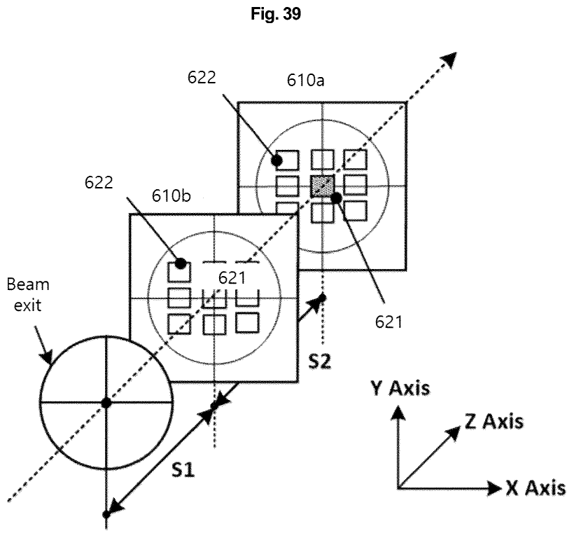

Alternatively, unlike FIG. 38, as shown in FIG. 39, the second test board 610b having the non-reference test target semiconductor device 622 may be first irradiated with the test beam, and subsequently, the first test board 610a having the reference test target semiconductor device 621 may be irradiated with the test beam that has been transmitted through the second test board 610b.

An error correction value may be calculated by using a reference error value of the reference test target semiconductor device 621 and the measured error value of the reference test target semiconductor device 621 (S940).

As described above, the reference error value of the reference test target semiconductor device 621 may be defined and determined. For example, the error correction value may be calculated by dividing the error value of the reference test target semiconductor device 621 that occurs by the test beam by the determined reference error value of the reference test target semiconductor device 621. In other words, the error correction value may be a value that compensates for a difference in error value that occurs in the reference test target semiconductor device 621 (a difference between the reference error value and the measured error value) according to a difference in dose between the test beam and the reference test beam. In other words, the error correction value may be a value that compensates for a difference in error value that occurs by the difference in dose between the test beam that is currently used and the reference test beam used to calculate the reference error value.

A reference error value of the non-reference test target semiconductor device 622 may be calculated from the measured error value of the non-reference test target semiconductor device 622 by using a distance S2 between the first test board 610a and the second test board 610b and the error correction value (S950).

A distance S1 between the beam source and the first test board 610a may be different from a distance S1+S2 between the beam source and the second test board 610b, a difference may occur in a dose of the test beam with which the first test board 610a is irradiated and a dose of the test beam with which the second test board 610b is irradiated according to a difference in distance. In detail, the dose of the test beam with which the second test board 610b is irradiated may be reduced in proportion to the square of the difference in distance S2 as compared with the dose of the test beam with which the first test board 610a is irradiated.

Therefore, the reference error value of the non-reference test target semiconductor device 622 may be calculated by multiplying the error value of the non-reference test target semiconductor device 622 that occurs by the test beam by the error correction value, and dividing a multiplication result by the square of the distance S2 between the first test board 610a and the second test board 610b since a value by which the dose spreads over distance is inversely proportional to the square of the distance. Accordingly, occurrence of a difference in error value according to a difference in dose of the test beam that is currently used may be compensated for, so that reliability of the error value of the non-reference test target semiconductor device 622 may be ensured.

Although two test boards 610a and 610b have been described and shown in FIGS. 38 and 39 as being arranged to overlap each other, embodiments are not limited thereto, and two or more test boards may be arranged to overlap each other.

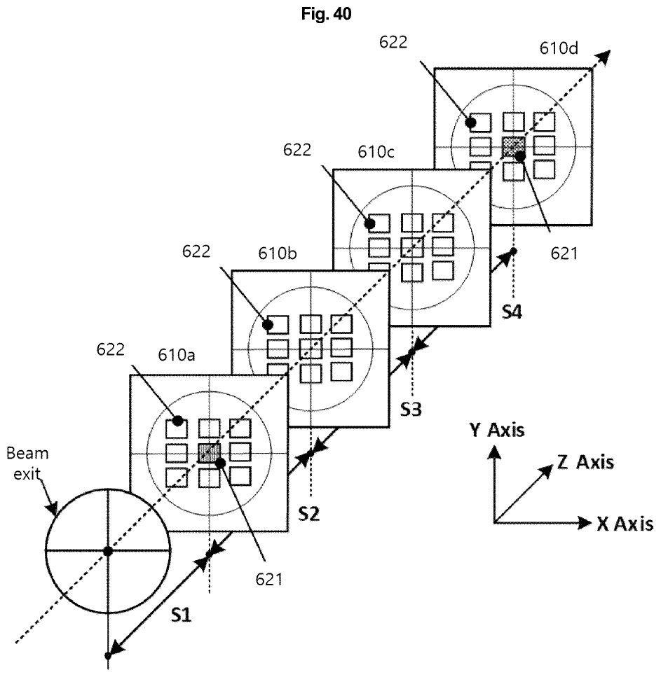

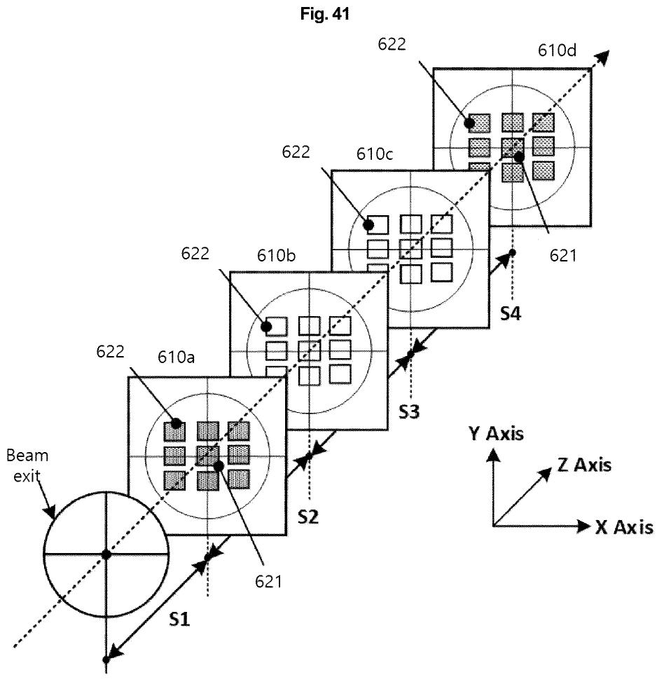

In detail, as shown in FIG. 40, first to fourth test boards 610a to 610d may be spaced apart from each other to overlap each other, and the first to fourth test boards 610a to 610d that are spaced apart from each other to overlap each other may be irradiated with the test beam, so that the first to fourth test boards 610a to 610d may be sequentially irradiated with the test beam. In this case, as shown in FIG. 40, at least one reference test target semiconductor device 621 may be arranged on the first test board 610a that is closest to the beam source and the fourth test board 610d that is farthest from the beam source.

Alternatively, as shown in FIG. 41, the first to fourth test boards 610a to 610d may be spaced apart from each other to overlap each other, such that only the reference test target semiconductor device 621 may be arranged on the first test board 610a that is closest to the beam source and the fourth test board 610d that is farthest from the beam source. In other words, the first test board 610a and the fourth test board 610d may be reference test boards on which only the reference test target semiconductor device 621 is disposed.

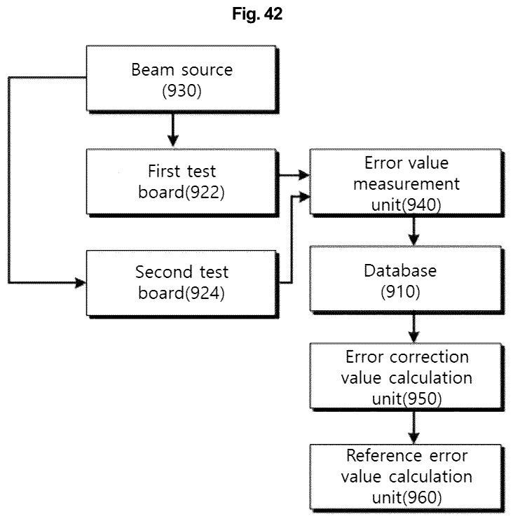

FIG. 42 is a block diagram for describing a system for evaluating a semiconductor device by using a reference semiconductor device according to a second embodiment of the present disclosure.

Referring to FIG. 42, according to an embodiment of the present disclosure, a system for evaluating a semiconductor device by using a reference semiconductor device may include a database 910, a first test board 922, a second test board 924, a beam source 930, an error value measurement unit 940, an error correction value calculation unit 950, and a reference error value calculation unit 960.

As described with reference to FIGS. 37 to 41, the database 910 may store a reference error value of the reference test target semiconductor device.

As described with reference to FIGS. 37 to 41, a plurality of reference test target semiconductor devices may be arranged in a test region of the first test board 922.

As described with reference to FIGS. 37 to 41, a plurality of non-reference test target semiconductor devices may be arranged in the test region of the second test board 924, and the second test board 924 may be spaced apart from the first test board 922 to overlap the first test board 922.

As described with reference to FIGS. 37 to 41, the beam source 930 may irradiate the test regions of the first and second test boards 922 and 924 with a test beam.

As described with reference to FIGS. 37 to 41, the error value measurement unit 940 may measure error values of the reference test target semiconductor device and the non-reference test target semiconductor device by the test beam from the first test board 922 and the second test board 924.

As described with reference to FIGS. 37 to 41, the error correction value calculation unit 950 may receive the reference error value of the reference test target semiconductor device, which is stored in the database 910, and the error value of the reference test target semiconductor device, which is measured by the error value measurement unit 940, and may calculate an error correction value by using the received values.

As described with reference to FIGS. 37 to 41, the reference error value calculation unit 960 may receive a distance between the first test board 922 and the second test board 924 and the error correction value from the error correction value calculation unit 950, and may calculate a reference error value of the non-reference test target semiconductor device from the error value of the non-reference test target semiconductor device, which is measured by the error value measurement unit 840, by using the received distance and the received error correction value.

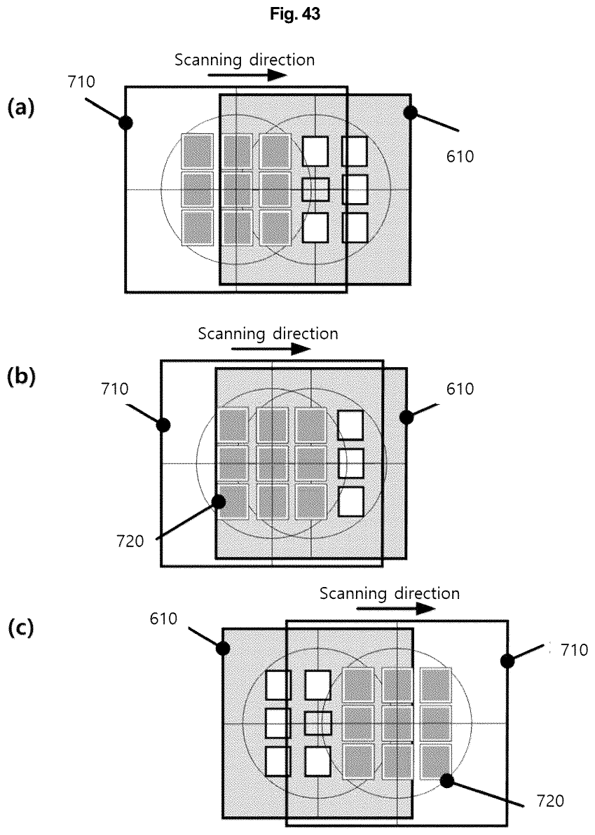

As a method that is different from the method described with reference to FIGS. 30 to 33, while the beam source and the test board are fixed, a reference test target semiconductor device may be irradiated with a test beam by using a beam characteristic control board. The above configuration will be described with reference to FIGS. 43 to 46.

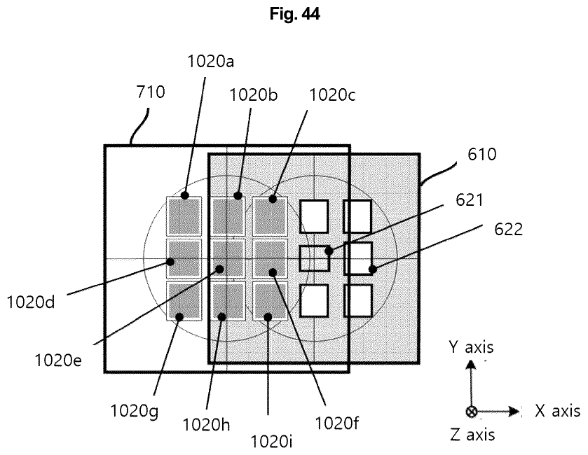

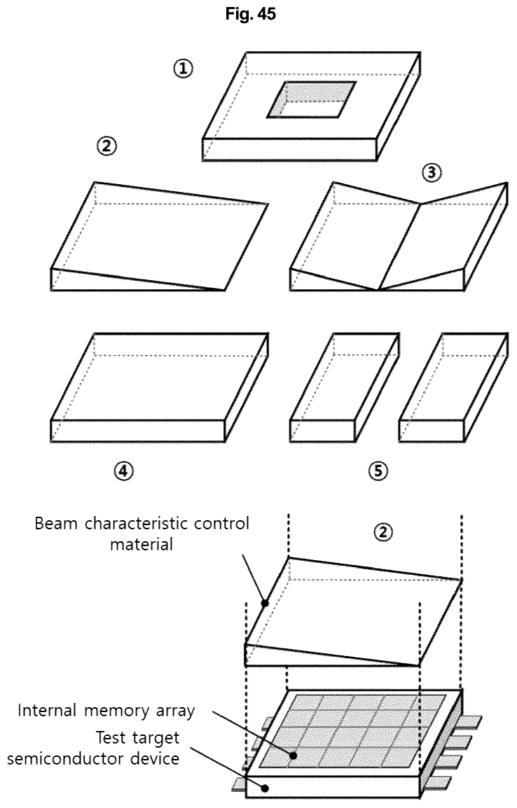

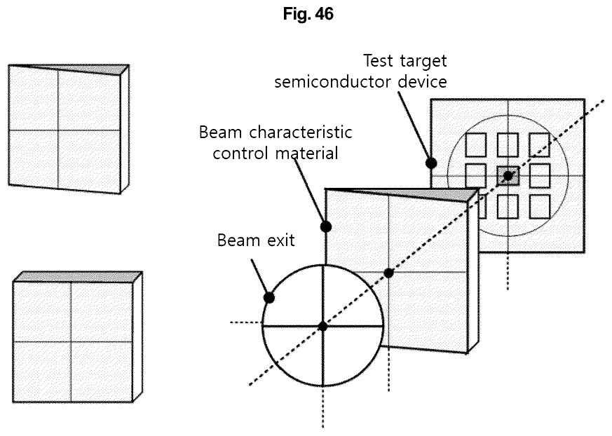

FIG. 43 is a view for describing a method for evaluating a semiconductor device by using a beam characteristic control board according to an embodiment of the present disclosure, FIG. 44 is a view for describing an arrangement of a beam characteristic control material in the beam characteristic control board according to the embodiment of the present disclosure, and FIGS. 45 and 46 are views for describing a structure of the beam characteristic control material in the beam characteristic control board according to the embodiment of the present disclosure.

Referring to FIG. 43, a beam characteristic control board 1010 on which a beam characteristic control material 1020 is arranged may be prepared. Unlike the configuration described with reference to FIGS. 30 to 33, while a beam source and a test board 610 are fixed so as not to move, the beam characteristic control board 1010 may be used to irradiate a reference test target semiconductor device with a test beam.

In other words, as shown in FIG. 43, the beam characteristic control board 1010 having the beam characteristic control material 1020 may be disposed between the beam source and the test board 610. In this state, the beam characteristic control board 1010 may be moved in one direction, and the test board 610 may be irradiated with the test beam while the beam characteristic control board 1010 is moved, so that a dose of the test beam with which the reference test target semiconductor device in the test board 610 is irradiated may be controlled.

In detail, in (a) of FIG. 43, as the beam characteristic control board 1010 is moved, the leftmost reference test target semiconductor devices on the test board 610 may be irradiated with the test beam that has been transmitted through the beam characteristic control material 1020 of the beam characteristic control board 1010, and central reference test target semiconductor devices and the rightmost reference test target semiconductor devices on the test board 610 may be irradiated with the test beam that has not been transmitted through the beam characteristic control material 1020. In (b) of FIG. 43, the leftmost reference test target semiconductor devices and the central reference test target semiconductor devices on the test board 610 may be irradiated with the test beam that has been transmitted through the beam characteristic control material 1020 of the beam characteristic control board 1010, and the rightmost reference test target semiconductor devices on the test board 610 may be irradiated with the test beam that has not been transmitted through the beam characteristic control material 1020. In addition, in (c) of FIG. 43, the rightmost reference test target semiconductor devices on the test board 610 may be irradiated with the test beam that has transmitted through the beam characteristic control material 1020 of the beam characteristic control board 1010, and the leftmost reference test target semiconductor devices and the central reference test target semiconductor devices on the test board 610 may be irradiated with the test beam that has not been transmitted through the beam characteristic control material 1020.

Although the beam characteristic control board 1010 has been shown in FIG. 43 as being moved in the X axis direction described with reference to FIG. 28, embodiments are not limited thereto, and it is obvious to those skilled in the art that the beam characteristic control board 1010 may be moved in the Y axis direction or the Z axis direction.

The beam characteristic control material 1020 disposed on the beam characteristic control board 1010 may be a material capable of controlling a dose and energy of the test beam, such as a particle moderator, a particle absorber, or an energy decomposer, and the beam characteristic control board 1010 may function as a collimator of the test beam according to a type and an arrangement of the beam characteristic control material 1020 in the beam characteristic control board 1010.

As shown in FIG. 44, for example, first to ninth beam characteristic control materials 1020a to 1020i may be provided in the beam characteristic control board 1010. According to one embodiment, the first to third beam characteristic control materials 1020a to 1020c arranged on the same axis in the X axis direction (arranged in the X axis direction) may be the same material, the fourth to sixth beam characteristic control materials 1020d to 1020f arranged on the same axis in the X axis direction (arranged in the X axis direction) may be the same material, and the seventh beam characteristic control material 1020g to 1020i arranged on the same axis in the X axis direction (arranged in the X axis direction) may be the same material. Alternatively, according to another embodiment, the first, fourth, and seventh beam characteristic control materials 1020a, 1020d, and 1020g may be the same material, the second, fifth, and eighth beam characteristic control materials 1020b, 1020e, and 1020h arranged on the same axis in the Y axis direction (arranged in the Y axis direction) may be the same material, and the third, sixth, and ninth beam characteristic control materials 1020c, 1020f, and 1020i arranged on the same axis in the Y axis direction (arranged in the Y axis direction) may be the same material. Alternatively, according to still another embodiment, the first to ninth beam characteristic control materials 1020a to 1020i may all be mutually different materials.

As described above, when the beam characteristic control materials arranged on the same axis in the X axis direction are the same material, or the beam characteristic control materials arranged on the same axis in the Y axis direction are the same material, an effect may be implemented with one evaluation of moving the beam characteristic control board 1010 in the Y axis direction or the X axis direction.

In detail, when the beam characteristic control materials arranged on the same axis in the X axis direction are the same, the irradiation of the test beam may be performed while the beam characteristic control board 1010 is moved in the Y axis direction, and, when the beam characteristic control materials arranged on the same axis in the Y axis direction are the same, the irradiation of the test beam may be performed while the beam characteristic control board 1010 is moved in the X axis direction, so that each of the test target semiconductor devices may be irradiated with the test beam having characteristics controlled by the beam characteristic control materials that are different from each other.

In addition, as shown in FIG. 45, a thickness of the beam characteristic control material 1020 in the beam characteristic control board 1010 may vary. The beam characteristic control material 1020 may be provided in a shape that surrounds an empty space in a central portion as shown in \textcircled{1} of FIG. 45, may be provided to have a thickness that gradually becomes thinner as the beam characteristic control material 1020 extends in one direction as shown in \textcircled{2} of FIG. 45, may be provided to have a thickness that gradually becomes thinner and gradually becomes thicker as the beam characteristic control material 1020 extends in one direction as shown in \textcircled{3} of FIG. 45, may be provided to have a predetermined thickness as shown in \textcircled{4} of FIG. 45, or may be provided to include two blocks having a predetermined thickness as shown in \textcircled{5} of FIG. 45.

In addition, as shown in FIG. 45, when a memory array is provided inside the test target semiconductor device, an evaluation resolution may be gradually increased as a distance between the beam characteristic control material and the test target semiconductor device becomes narrower. In other words, according to a degree of integration of the test target semiconductor device, the distance between the beam characteristic control material and the test target semiconductor device may be controlled, so that an error value by the irradiation of the test beam may be measured for one memory cell in the memory array or for a group of a plurality of memory cells.

In addition, as shown in FIG. 46, the beam exit, the beam characteristic control material, and the test target semiconductor device on the test board may be aligned.

FIGS. 44 to 46 illustrate shapes and arrangement relation of the beam characteristic control materials 1020 in the beam characteristic control board 1010, and the technical idea of the present disclosure is not limited to the shape and the arrangement of the beam characteristic control material 1020 shown in FIGS. 44 to 46.

As described above, according to an embodiment of the present disclosure, evaluation may be performed on reference values, test beams that are references, and test target semiconductor devices shown in first to fifth cases of <Table 12> below.

In detail, uniformity of the test beam at a given position may vary according to a position of the test target semiconductor device, dispersion (diversion) of the test beam according to a distance may gradually become greater as a position becomes farther away from the test beam, and attenuation (degradation) of the test beam may occur when the test beam overlaps an energy control board. When two items described above are measured, a correction value, a reference value, and a reference value may be obtained.

TABLE 12

| Classifi- | | | |
|---|---|---|---|
| cation | Beam | Device | Evaluation result |
| Case 1 | Unknown | Unknown | Reference dose, device |
| | | | reference error calculation |
| Case 2 | Reference | Unknown | Device reference error |
| | Beam | | calculation, position |
| | | | correction value |
| Case 3 | Unknown | Reference Device | Device dose calculation, |
| | | | dose profile |
| Case 4 | Reference | Reference Device, | Device reference error |
| | Beam | Unknown Devices | calculation, position |
| | | | correction value |
| Case 5 | Reference | Reference Board, | Device reference error |
| | Beam | Unknown Multiple | calculation, distance |
| | | Boards | correction value, position |
| | | | correction value |

Although the exemplary embodiments of the present invention have been described in detail above, the scope of the present invention is not limited to a specific embodiment, and shall be interpreted by the appended claims. In addition, it is to be understood by a person having ordinary skill in the art that various changes and modifications can be made without departing from the scope of the present invention.

### INDUSTRIAL APPLICABILITY

According to an embodiment of the present disclosure, a method for evaluating a radiation of a semiconductor device and a system for evaluating a radiation of a semiconductor device may be used to evaluate an SRAM, a flash memory, a DRAM, a cache memory, a logic IC, an image sensor device, a display device, a power IC, an RF IC, an SSD, an RRAM, a PRAM, an MRAM, and the like. In addition, according to an embodiment of the present disclosure, a method for evaluating a radiation of a semiconductor device, a system for evaluating a radiation of a semiconductor device, a method for evaluating a beam characteristic, and a system for evaluating a beam characteristic, by using a reference semiconductor device, may be used to evaluate various beam characteristics used in evaluation of semiconductor devices, and perform evaluation on various semiconductor devices.

1-4. (canceled)

5: A system for evaluating a semiconductor device, which is for measuring an error value of a test target semiconductor device arranged on a test board, the system configured to:
irradiate a test region in which the test target semiconductor device is arranged with a test beam to measure the error value of the test target semiconductor device by the test beam.

6: The system of claim 5, further comprising an algorithm board configured to measure and count an error that occurs in the test target semiconductor device.

7: The system of claim 6, further comprising:
a beam irradiation region in which the test board is arranged, and irradiated with the test beam; and
a control region isolated from the beam irradiation region, and unirradiated with the test beam.

8: The system of claim 7, further comprising:
a base control system disposed in the control region, and configured to receive the error value of the test target semiconductor device from the algorithm board; and
a base analysis system configured to analyze the error value of the test target semiconductor device received from the base control system.

9-16. (canceled)

17: The system of claim 5, wherein a plurality of test target semiconductor devices are in the test region.

18: The system of claim 17, wherein the test target semiconductor devices are arranged two-dimensionally in rows and columns.
